(19) United States
(12) Patent Application Publication
(10) Pub. No.: US 2025/0061927 A1
(43) Pub. Date: Feb. 20, 2025

(54) MEMORY

(71) Applicant: CXMT Corporation, Hefei City (CN)

(72) Inventor: Jia WANG, Hefei City (CN)

(73) Assignee: CXMT Corporation, Hefei City (CN)

(21) Appl. No.: 18/936,784

(22) Filed: Nov. 4, 2024

Related U.S. Application Data
(63) Continuation of application No. PCT/CN2024/078017, filed on Feb. 22, 2024.
(63) Continuation of application No. PCT/CN2023/097747, filed on Jun. 1, 2023.

(30) Foreign Application Priority Data
Mar. 3, 2023 (CN) 202310194644.8
Mar. 3, 2023 (CN) 202310216310.6

(51) Int. Cl. G11C 7/10

(52) U.S. Cl. CPC G11C 7/1048; G11C 2207/107

(57) ABSTRACT

Embodiments of the present disclosure provide a memory, including multiple data input/output pins and a data input/output selector. The multiple data input/output pins are configured to receive or output working serial data when the memory is in a working mode. One of the data input/output pins is a target data input/output pin. The target data input/output pin is configured to receive test serial data when the memory is in a test mode. A first input terminal of the data input/output selector receives the test serial data received by the target data input/output pin. The data input/output selector is configured to: in the test mode, separately transmit, to transmission paths corresponding to one corresponding data input/output pin in the memory, each bit of data in the test serial data received by the target data input/output pin.

### CROSS-REFERENCE TO RELATED APPLICATIONS

This is a continuation of International Patent Application No. PCT/CN2024/078017 filed on Feb. 22, 2024 and International Patent Application No. PCT/CN2023/097747 filed on Jun. 1, 2023, which claim priority to Chinese Patent Application No. 202310216310.6 filed on Mar. 3, 2023 and Chinese Patent Application No. 202310194644.8 filed on Mar. 3, 2023. The disclosures of the above-referenced applications are hereby incorporated by reference in their entirety.

### BACKGROUND

With widespread application of various memories, e.g., widely applied dynamic random access memories (DRAM), in an actual application, a packaged memory needs to be tested to ensure product reliability.

Therefore, how to improve test efficiency of the memory becomes a problem that needs to be considered.

### SUMMARY

The present disclosure relates to but is not limited to a memory.

Embodiments of the present disclosure provide a memory, to improve test efficiency of the memory.

According to some embodiments, the present disclosure provides a memory, including:
multiple data input/output pins, configured to receive or output working serial data when the memory is in a working mode, one of the data input/output pins being a target data input/output pin, and the target data input/output pin being configured to receive test serial data when the memory is in a test mode; and
a data input/output selector, a first input terminal of the data input/output selector receiving the test serial data received by the target data input/output pin, and
the data input/output selector being configured to: in the test mode, separately transmit, to transmission paths corresponding to one corresponding data input/output pin in the memory, each bit of data in the test serial data received by the target data input/output pin.

### BRIEF DESCRIPTION OF DRAWINGS

The accompanying drawings herein, which are incorporated in and constitute a part of the specification, illustrate embodiments consistent with the present disclosure, and serve to explain the principles of the embodiments of the present disclosure together with the specification.

FIG. 1 is an example diagram of a pin architecture of a memory according to an embodiment of the present disclosure;

FIG. 2 is a schematic diagram of transmitting read and write data according to an embodiment of the present disclosure;

FIG. 3 is an example structural diagram of a memory according to an embodiment of the present disclosure;

FIG. 4 is an example structural diagram of a memory according to an embodiment of the present disclosure;

FIG. 5 is an example structural diagram of a memory according to another embodiment of the present disclosure;

FIG. 6 is an example structural diagram of a memory according to another embodiment of the present disclosure;

FIG. 7 is an example structural diagram of a memory according to another embodiment of the present disclosure;

FIG. 8 is a schematic structural diagram of a memory array according to another embodiment of the present disclosure;

FIG. 9 is a schematic structural diagram of a second selector according to another embodiment of the present disclosure;

FIG. 10 is a schematic structural diagram of a signal generation circuit according to another embodiment of the present disclosure; and

FIG. 11 is a schematic diagram of transmitting write data according to an embodiment of the present disclosure.

The foregoing accompanying drawings already show clear embodiments of the present disclosure, which are described in more detail below. These accompanying drawings and text descriptions are not intended to limit the scope of the concept of the present disclosure in any manner, but to describe the concept of the present disclosure for a person skilled in the art with reference to specific embodiments.

### DETAILED DESCRIPTION

Example embodiments are described in detail herein, and examples thereof are shown in the accompanying drawings. When the following descriptions relate to the accompanying drawings, unless otherwise indicated, the same numbers in different accompanying drawings represent the same or similar elements. Implementations described in the following example embodiments do not represent all implementations consistent with the present disclosure. On the contrary, they are merely examples of apparatuses and methods that are consistent with some aspects of the present disclosure as detailed in the appended claims.

The terms “include” and “have” in the present disclosure are utilized to denote an open-ended inclusion, and indicate that other elements/components/etc. can be present in addition to the elements/components/etc. listed. The terms “first”, “second”, and the like are utilized only for labeling purposes, and do not limit the quantity of objects thereof. In addition, different elements and areas in the accompanying drawings are merely shown schematically. Therefore, the present disclosure is not limited to a size or a distance shown in the accompanying drawings.

The following describes the technical solutions of the present disclosure in detail through specific embodiments. The following several specific embodiments may be combined with each other. A same or similar concept or process may not be described in some embodiments. The following describes the embodiments of the present disclosure with reference to the accompanying drawings.

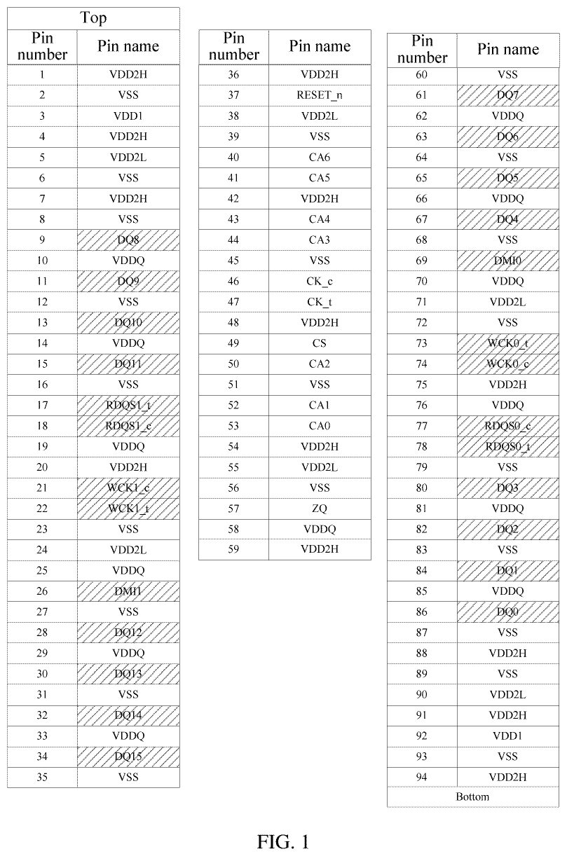

FIG. 1 is an example diagram of a pin architecture of a memory according to an embodiment of the present disclosure. As shown in FIG. 1, the memory includes multiple pins, and the multiple pins may be classified into power pins, data/address pins, and control command pins.

The power pins may include a VDD1 pin, a VDD2H pin, a VDD2L pin, and a VDDQ pin. The VDD1 pin receives VDD1 to supply power to a memory core. The VDD2H pin receives VDD2H to supply power to the memory core. The VDD2L pin receives VDD2L to supply power to the memory core as well. The VDDQ pin receives VDDQ to supply power to an I/O buffer. In an actual application, the memory may internally have three sets of voltages, which are respectively VDD1, VDD2, and VDDQ. VDD2 may include VDD2H and VDD2L. VDD1 and VDD2 represent working voltages of the memory core, and VDD1 and VDD2 have different voltage values. VDD2H represents a relatively high voltage value. VDD2L represents a relatively low voltage value. VDDQ represents a high-quality voltage subjected to noise filtering, with large anti-interference strength.

The data/address pins may include DQ0 to DQ15 pins and CA0 to CA6 pins. In an actual application, the memory internally includes a memory array, the memory array includes multiple memory cells, and each memory cell has a corresponding row and a corresponding column. During a read operation or a write operation, a row and a column of the memory array on which read or write is to be performed need to be first specified to determine a memory cell on which read or write is to be performed. The CA0 to CA6 pins may receive read addresses or write addresses. The read address includes a row and a column of the memory array on which read is performed, and the write address includes a row and a column of the memory array on which write is performed. The DQ0 to DQ15 pins may receive write data and output read data. During a read operation, the DQ0 to DQ15 pins output data read from the memory cell. During a write operation, the DQ0 to DQ15 pins receive data to be written into the memory cell.

The control command pins may include WCK pins, RDQS pins (also referred to as read strobe pins), DMI pins, CK pins, and the like. The WCK pins include a WCK1_t pin, a WCK1_c pin, a WCK0_t pin, and a WCK0_c pin. The RDQS pins include an RDQS1_t pin, an RDQS1_c pin, an RDQS0_t pin, and an RDQS0_c pin. The DMI pins include a DMI0 pin and a DMI1 pin. The CK pins include a CK_t pin and a CK_c pin. The WCK1_t pin receives WCK1_t. The WCK1_c pin receives WCK1_c. The WCK0_t pin receives WCK0_t. The WCK0_c pin receives WCK0_c. The RDQS1_t pin receives RDQS1_t. The RDQS1_c pin receives RDQS1_c. The RDQS0_t pin receives RDQS0_t. The RDQS0_c pin receives RDQS0_c. The DMI0 pin receives DMI0. The DMI1 pin receives DMI1. The CK_t pin receives CK_t. The CK_c pin receives CK_c.

WCK1_t, WCK1_c, WCK0_t, and WCK0_c represent write clocks, and the write clocks are configured to sample the write data received by DQ0 to DQ15. In an actual application, WCK1_t and WCK1_c are configured to sample write data received by the DQ8 to DQ15 pins, and WCK0_t and WCK0_c are configured to sample write data received by DQ0 to DQ7 pins. WCK1_t, WCK1_c, WCK0_t, and WCK0_c may run at twice or four times a frequency of CK_t/CK_c to increase a sampling rate. RDQS1_t, RDQS1_c, RDQS0_t, and RDQS0_c represent read clocks, and are also referred to as read strobe signals. The read clocks are configured to sample the read data output by DQ0 to DQ15. In an actual application, RDQS1_t and RDQS1_c are configured to sample read data output by the DQ8 to DQ15 pins, and RDQS0_t and RDQS0_c are configured to sample read data output by the DQ0 to DQ7 pins.

DMI1 and DMI0 represent data mask (DM) signals, and the data mask signals are configured to mask the write data received by the DQ0 to DQ15 pins, to determine write data to be written into the memory cell. In an actual application, DMI1 is configured to mask write data received by the DQ8 to DQ15 pins, and DMI0 is configured to mask write data received by the DQ0 to DQ7 pins.

CK_t and CK_c represent command address clocks, and the command address clocks are configured to sample the read address or the write address. In an actual application, all commands, addresses, and input control signals are sampled at an intersection of a rising edge of CK_t and a falling edge of CK_c.

The control command pins may further include a ZQ pin, a RESET pin, a CS pin, and the like. The ZQ pin receives ZQ. ZQ represents a calibration signal, and the calibration signal is configured to calibrate output drive strength. The RESET_n pin receives RESET_n. RESET_n represents a reset signal, and the reset signal is configured to reset the memory to a default state during initialization. The CS pin receives CS. CS represents a chip select signal, and the chip select signal is configured to select a target die.

It should be noted that pins related to data input/output include the DQ0 to DQ15 pins, the WCK1_t pin, the WCK1_c pin, the WCK0_t pin, the WCK0_c pin, the RDQS1_t pin, the RDQS1_c pin, the RDQS0_t pin, the RDQS0_c pin, the DMI1 pin, and the DMI0 pin. It may be learned that 26 pins are related to data input/output.

In an actual application, to ensure reliability of a memory product, the memory needs to be tested after the memory is packaged. A memory test involves write and read on the memory, and the write and the read on the memory depend on pins of the memory.

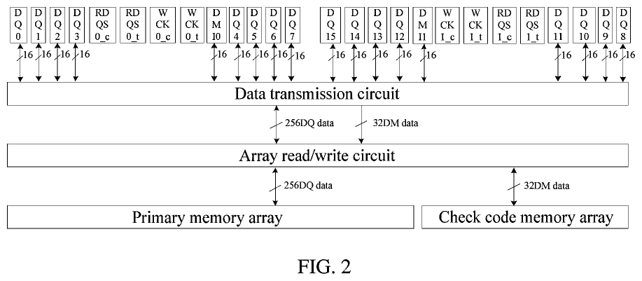

As shown in FIG. 2, FIG. 2 is an example diagram of transmitting read and write data according to an embodiment of the present disclosure. Taking a write scenario as an example, each of the DQ0 to DQ15 pins receives 16-bit write data, the WCK0_t pin receives WCK0_t, the WCK0_c pin receives WCK0_c, WCK0_t and WCK0_c are configured to sample the write data received by the DQ0 to DQ7 pins, the WCK1_t pin receives WCK1_t, the WCK1_c pin receives WCK1_c, and WCK1_t and WCK1_c are configured to sample the write data received by the DQ8 to DQ15 pins.

As shown in FIG. 2, when the memory is in a test mode, each DQ pin receives 16-bit write data, and 256-bit data is received by the DQ0 to DQ15 pins in total and stored into a primary memory array. 16-bit check code data is received by each of DMI0 and DMI1 and stored into a check code memory array.

A data transmission circuit (data path circuit) transmits, to an array read/write circuit, the 256-bit data received by the DQ0 to DQ15 pins, the 16-bit check code data received by the DMI0 pin, and the 16-bit check code data received by the DMI1 pin.

Taking a read scenario in the test mode of the memory as an example, the array read/write circuit reads data from the primary memory array and reads check code data from the check code memory array, and transmits the data to the data transmission circuit. The data transmission circuit transmits the read data to the DQ pin, and transmits the check code data to the DMI pin. As shown in FIG. 2, the array read/write circuit reads 256-bit data from 256 memory cells of the primary memory array and reads 32-bit check code data from 32 memory cells of the check code memory array, and transmits the 256-bit data and the 32-bit check code data to the data transmission circuit. The data transmission circuit transmits each piece of 16-bit data to each of the DQ0 to DQ15 pins, and separately transmits the two pieces of 16-bit check code data to the DMI0 pin and the DMI1 pin. Then, the RDQS0_t pin receives RDQS0_t, the RDQS0_c pin receives RDQS0_c, RDQS0_t and RDQS0_c are configured to sample the read data output by the DQ0 to DQ7 pins. The RDQS1_t pin receives RDQS1_t, the RDQS1_c pin receives RDQS1_c, and RDQS1_t and RDQS1_c are configured to sample the read data output by the DQ8 to DQ15 pins.

In a test process of the memory, if data transmission, signal transmission, or the like is performed through all pins, a quantity of simultaneously tested memories is limited, and test efficiency is reduced.

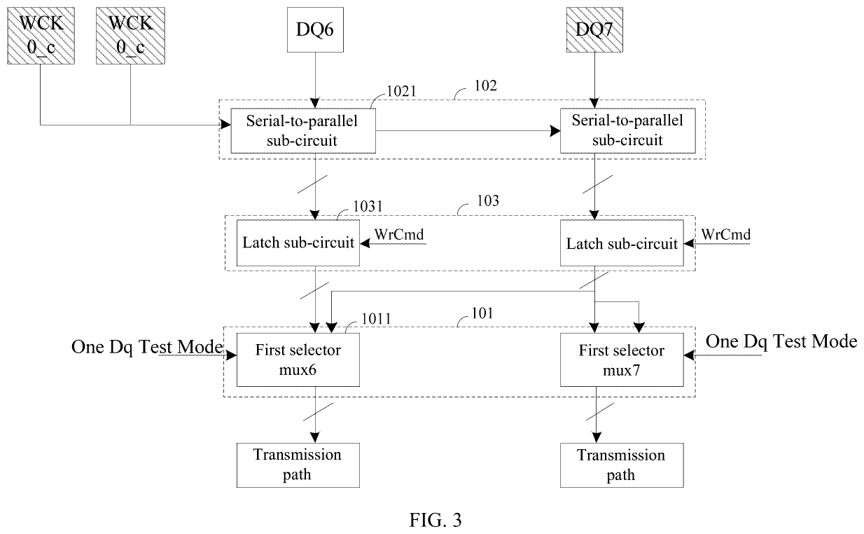

FIG. 3 is an example structural diagram of a memory according to an embodiment of the present disclosure. The memory provided in this embodiment is configured to reduce a quantity of utilized pins of the memory in a test process. As shown in FIG. 3, the memory includes a data input/output selector 101. A first input terminal of the data input/output selector 101 receives serial data received by a target data input/output pin. The target data input/output pin may be any one of multiple data input/output pins in the memory. The data input/output selector 101 is configured to: in a test mode, transmit, to transmission paths corresponding to one corresponding data input/output pin in the memory, each bit of data in the serial data received by the target data input/output pin. In the test mode, the serial data received by the target data input/output pin is transmitted to the transmission paths corresponding to each data input/output pin, and the same data is written into all memory cells corresponding to each data input/output pin. Therefore, in the test mode, write data needs to be received only through the target data input/output pin. In this way, only one data input/output pin is required during a test, so that a quantity of utilized data input/output pins is reduced, thereby increasing a quantity of simultaneously tested memories, and improving test efficiency.

The transmission path corresponding to the data input/output pin is a path for transmitting, to the memory cell, e.g. the data transmission circuit and the array read/write circuit in the foregoing embodiment, write data received by the data input/output pin. Because each data input/output pin may receive one piece of multi-bit serial data, only 1-bit data can be written into each memory cell, and serial data received by each data input/output pin may be written into multiple memory cells, each data input/output pin may correspond to multiple transmission paths.

In the test mode, a primary memory array in the memory may receive and store, through the multiple transmission paths corresponding to each data input/output pin, the serial data received by the target data input/output pin. Therefore, in the primary memory array, multiple memory cells corresponding to the multiple transmission paths of each data input/output pin store the same data in the serial data received by the target data input/output pin, i.e. the multiple memory cells store the same data.

In an actual application, the memory provided in this embodiment may be applied to tests of various memory chips. For example, the memory may be applied to, including but not limited to, a low power double data rate synchronous dynamic random access memory (LPDDR SDRAM), e.g., LPDDR5. The memory in this embodiment may be considered as a device under test (DUT).

In some embodiments, the data input/output selector 101 further includes a second input terminal. The second input terminal receives multiple pieces of serial data received by the multiple data input/output pins in the memory. It may be understood that the memory includes multiple data input/output pins, e.g. DQ0 to DQ15 pins. Each data input/output pin may receive one piece of multi-bit serial data. In this case, the data input/output selector 101 may receive the multiple pieces of serial data received by the multiple data input/output pins. That is, the data input/output selector 101 may receive one piece of multi-bit serial data received by each data input/output pin in the memory, and in a working mode, separately transmit, to the transmission paths corresponding to each data input/output pin, the one piece of multi-bit serial data received by the data input/output pin. The working mode may be a write operation in a non-test mode. In this embodiment, in the test mode, the memory may separately transmit, to the transmission paths corresponding to the one corresponding data input/output pin, each bit of data in the serial data received by the target data input/output pin, thereby reducing a quantity of utilized pins in a test process, and improving test efficiency. In addition, in the working mode, the memory may separately transmit, to the transmission paths corresponding to the one corresponding data input/output pin, the serial data received by the data input/output pin, thereby ensuring normal working of the memory.

In this example, the data input/output selector 101 may receive the multiple pieces of serial data received by the multiple data input/output pins in the memory and multi-bit data in serial data received by any one of the data input/output pins. When the memory receives a test indication signal (OneDqTestMode) in the test mode, each bit of data in one piece of serial data received by any one of the data input/output pins is separately transmitted to the transmission paths corresponding to the one corresponding data input/output pin. When the memory is in the working mode, the serial data received by the one corresponding data input/output pin is separately transmitted to the transmission paths corresponding to the one corresponding data input/output pin.

Transmission paths corresponding to a specific data input/output pin into which each bit of data in the serial data received by the target data input/output pin is to be written may be determined based on a sequence of transmitting each bit of data in the serial data received by the target data input/output pin. For example, each bit of data in the serial data received by the target data input/output pin is successively written into transmission paths corresponding to each of the DQ0 to DQ15 pins based on a sequence of transmitting each bit of data in the serial data.

In some embodiments, as shown in FIG. 3, the data input/output selector 101 includes multiple first selectors 1011, each of the first selectors 1011 corresponds to one data input/output pin, a first input terminal of each of the first selectors 1011 receives 1-bit data in the serial data received by the target data input/output pin, and a second input terminal of each of the first selectors 1011 receives serial data received by a corresponding data input/output pin. Therefore, in the test mode, each first selector 1011 may transmit, to transmission paths corresponding to the corresponding data input/output pin, 1-bit data in the received serial data received by the target data input/output pin; and in the working mode, each first selector 1011 may further transmit, to transmission paths corresponding to the corresponding data input/output pin, the serial data received by the corresponding data input/output pin.

For example, FIG. 11 is an example diagram of transmitting write data according to an embodiment of the present disclosure. With reference to FIG. 3 and FIG. 11, FIG. 3 shows only the DQ6 pin and the DQ7 pin. It may be understood that the memory includes but is not limited to the DQ6 pin and the DQ7 pin. The memory may include 16 DQ pins in total, which are the DQ0 to DQ15 pins. The data input/output selector may include 16 first selectors, and the 16 first selectors are marked as mux0 to mux15. The DQ0 pin corresponds to mux0, the DQ1 pin corresponds to mux1, the DQ2 pin corresponds to mux2, the DQ3 pin corresponds to mux3, and so on, until the DQ15 pin corresponds to mux15. That the target data input/output pin is the DQ7 pin is taken as an example. A first input terminal of mux0 receives the first bit of data in serial data received by the DQ7 pin, and a second input terminal of mux0 receives serial data received by the DQ0 pin. A first input terminal of mux1 receives the second bit of data in the serial data received by the DQ7 pin, and a second input terminal of mux1 receives serial data received by the DQ1 pin. A first input terminal of mux2 receives the third bit of data in the serial data received by the DQ7 pin, and a second input terminal of mux2 receives serial data received by the DQ2 pin. A first input terminal of mux3 receives the fourth bit of data in the serial data received by the DQ7 pin, and a second input terminal of mux3 receives serial data received by the DQ3 pin. A first input terminal of mux4 receives the fifth bit of data in the serial data received by the DQ7 pin, and a second input terminal of mux4 receives serial data received by the DQ4 pin. A first input terminal of mux5 receives the sixth bit of data in the serial data received by the DQ7 pin, and a second input terminal of mux5 receives serial data received by the DQ5 pin. A first input terminal of mux6 receives the seventh bit of data in the serial data received by the DQ7 pin, and a second input terminal of mux6 receives serial data received by the DQ6 pin. A first input terminal of mux7 receives the eighth bit of data in the serial data received by the DQ7 pin, and a second input terminal of mux7 receives the serial data received by the DQ7 pin. A first input terminal of mux8 receives the ninth bit of data in the serial data received by the DQ7 pin, and a second input terminal of mux8 receives serial data received by the DQ8 pin. A first input terminal of mux9 receives the tenth bit of data in the serial data received by the DQ7 pin, and a second input terminal of mux9 receives serial data received by the DQ9 pin. A first input terminal of mux10 receives the eleventh bit of data in the serial data received by the DQ7 pin, and a second input terminal of mux10 receives serial data received by the DQ10 pin. A first input terminal of mux11 receives the twelfth bit of data in the serial data received by the DQ7 pin, and a second input terminal of mux11 receives serial data received by the DQ11 pin. A first input terminal of mux12 receives the thirteenth bit of data in the serial data received by the DQ7 pin, and a second input terminal of mux12 receives serial data received by the DQ12 pin. A first input terminal of mux13 receives the fourteenth bit of data in the serial data received by the DQ7 pin, and a second input terminal of mux13 receives serial data received by the DQ13 pin. A first input terminal of mux14 receives the fifteenth bit of data in the serial data received by the DQ7 pin, and a second input terminal of mux14 receives serial data received by the DQ14 pin. A first input terminal of mux15 receives the sixteenth bit of data in the serial data received by the DQ7 pin, and a second input terminal of mux15 receives serial data received by the DQ15 pin. Herein, “first”, “second”, and “sixteenth” each may be a sequence in which each bit of data in the serial data is transmitted to DQ7.

Correspondingly, in the test mode, mux0 transmits, to transmission paths corresponding to the DQ0 pin, the first bit of data in the serial data received by the DQ7 pin; mux1 transmits, to transmission paths corresponding to the DQ1 pin, the second bit of data in the serial data received by the DQ7 pin; mux2 transmits, to transmission paths corresponding to the DQ2 pin, the third bit of data in the serial data received by the DQ7 pin; mux3 transmits, to transmission paths corresponding to the DQ3 pin, the fourth bit of data in the serial data received by the DQ7 pin; mux4 transmits, to transmission paths corresponding to the DQ4 pin, the fifth bit of data in the serial data received by the DQ7 pin; mux5 transmits, to transmission paths corresponding to the DQ5 pin, the sixth bit of data in the serial data received by the DQ7 pin; mux6 transmits, to transmission paths corresponding to the DQ6 pin, the seventh bit of data in the serial data received by the DQ7 pin; mux7 transmits, to transmission paths corresponding to the DQ7 pin, the eighth bit of data in the serial data received by the DQ7 pin; mux8 transmits, to transmission paths corresponding to the DQ8 pin, the ninth bit of data in the serial data received by the DQ7 pin; mux9 transmits, to transmission paths corresponding to the DQ9 pin, the tenth bit of data in the serial data received by the DQ7 pin; mux10 transmits, to transmission paths corresponding to the DQ10 pin, the eleventh bit of data in the serial data received by the DQ7 pin; mux11 transmits, to transmission paths corresponding to the DQ11 pin, the twelfth bit of data in the serial data received by the DQ7 pin; mux12 transmits, to transmission paths corresponding to the DQ12 pin, the thirteenth bit of data in the serial data received by the DQ7 pin; mux13 transmits, to transmission paths corresponding to the DQ13 pin, the fourteenth bit of data in the serial data received by the DQ7 pin; mux14 transmits, to transmission paths corresponding to the DQ14 pin, the fifteenth bit of data in the serial data received by the DQ7 pin; and mux15 transmits, to transmission paths corresponding to the DQ15 pin, the sixteenth bit of data in the serial data received by the DQ7 pin.

In the working mode, mux0 transmits, to the transmission paths corresponding to the DQ0 pin, the serial data received by the DQ0 pin; mux1 transmits, to the transmission paths corresponding to the DQ1 pin, the serial data received by the DQ1 pin; mux2 transmits, to the transmission paths corresponding to the DQ2 pin, the serial data received by the DQ2 pin; mux3 transmits, to the transmission paths corresponding to the DQ3 pin, the serial data received by the DQ3 pin; mux4 transmits, to the transmission paths corresponding to the DQ4 pin, the serial data received by the DQ4 pin; mux5 transmits, to the transmission paths corresponding to the DQ5 pin, the serial data received by the DQ5 pin; mux6 transmits, to the transmission paths corresponding to the DQ6 pin, the serial data received by the DQ6 pin; mux7 transmits, to the transmission paths corresponding to the DQ7 pin, the serial data received by the DQ7 pin; mux8 transmits, to the transmission paths corresponding to the DQ8 pin, the serial data received by the DQ8 pin; mux9 transmits, to the transmission paths corresponding to the DQ9 pin, the serial data received by the DQ9 pin; mux10 transmits, to the transmission paths corresponding to the DQ10 pin, the serial data received by the DQ10 pin; mux11 transmits, to the transmission paths corresponding to the DQ11 pin, the serial data received by the DQ11 pin; mux12 transmits, to the transmission paths corresponding to the DQ12 pin, the serial data received by the DQ12 pin; mux13 transmits, to the transmission paths corresponding to the DQ13 pin, the serial data received by the DQ13 pin; mux14 transmits, to the transmission paths corresponding to the DQ14 pin, the serial data received by the DQ14 pin; and mux15 transmits, to the transmission paths corresponding to the DQ15 pin, the serial data received by the DQ15 pin.

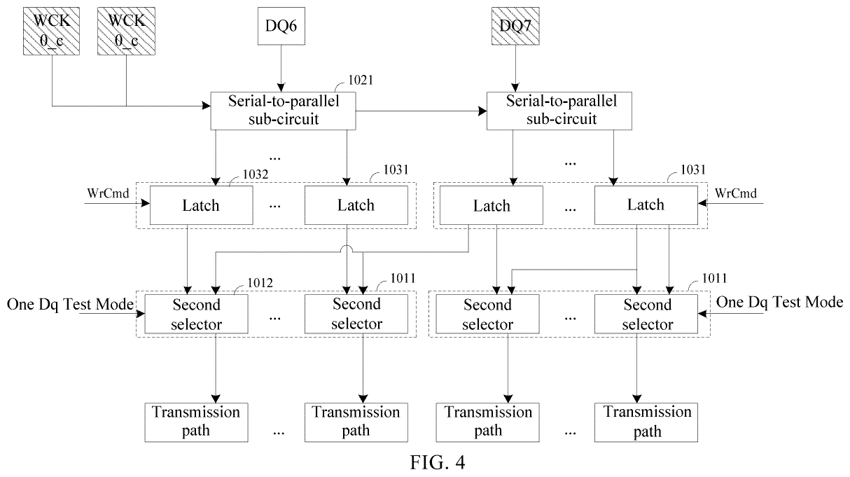

In this example, as shown in FIG. 4, each of the first selectors 1011 includes multiple second selectors 1012, and each of the second selectors 1012 corresponds to one transmission path of one data input/output pin. A first input terminal of each of the second selectors 1012 receives 1-bit data in the serial data received by the target data input/output pin, and a second input terminal of each of the second selectors 1012 receives 1-bit data in serial data received by a corresponding data input/output pin. It may be understood that each of the first selectors 1011 corresponds to one data input/output pin, and each of the first selectors 1011 includes multiple second selectors 1012. In this case, multiple second selectors 1012 in the same first selector 1011 correspond to the same data input/output pin. Each of the second selectors 1012 is configured to: in the test mode, transmit, to one transmission path of the corresponding data input/output pin, 1-bit data in the serial data received by the target data input/output pin; and in the working mode, transmit, to one transmission path of the corresponding data input/output pin, 1-bit data in the serial data received by the corresponding data input/output pin. In this embodiment, one transmission path of the data input/output pin may be understood as a transmission path of writing, into one memory cell, 1-bit data in serial data received by the data input/output pin.

In this example, that the DQ7 pin is the target data input/output pin is taken as an example. The DQ7 pin and the DQ6 pin each correspond to multiple second selectors. A first input terminal and a second input terminal of each of the second selectors corresponding to the DQ7 pin each receive 1-bit data in serial data received by the DQ7 pin. A first input terminal of each of the second selectors corresponding to the DQ6 pin receives 1-bit data in the serial data received by the DQ7 pin, and a second input terminal thereof receives 1-bit data in serial data received by the DQ6 pin. In the test mode, each of the second selectors corresponding to the DQ7 pin transmits the received 1-bit data in the serial data corresponding to the DQ7 pin to one transmission path of the DQ7 pin, and each of the second selectors corresponding to the DQ6 pin transmits the received 1-bit data in the serial data of the DQ7 pin to one transmission path of the DQ6 pin. In the working mode, each of the second selectors corresponding to the DQ7 pin transmits the received 1-bit data in the serial data corresponding to the DQ7 pin to one transmission path of the DQ7 pin, and each of the second selectors corresponding to the DQ6 pin transmits the received 1-bit data in the serial data corresponding to the DQ6 pin to one transmission path of the DQ6 pin.

In an actual application, during a write operation, the memory transmits data to one memory cell through one bit line, and only 1 bit can be written into one memory cell when data is written into the memory cell in the memory. For example, when data needs to be written into a memory cell, e.g. 1, a word line of a row in which the memory cell is located may be selected through a row decoder, to control a transistor M in the memory cell to be conducted. A logical level of the bit line is set to 1, so that a capacitor C is charged, i.e. 1 is written into the memory cell. On the contrary, if 0 is to be written, the logical level of the bit line is set to 0, so that the capacitor C is discharged, i.e. 0 is written to the memory cell.

Therefore, when the serial data received by the data input/output pin is written into the memory cell, the multi-bit serial data received by the data input/output pin may be first converted into multiple pieces of 1-bit parallel data, and the multi-bit serial data received by the data input/output pin is separately written into different memory cells at the same time through different bit lines in one write operation.

In some embodiments, the memory may include a serial-to-parallel circuit 102. As shown in FIG. 3, an input terminal of the serial-to-parallel circuit 102 is connected to the multiple data input/output pins. The serial-to-parallel circuit 102 may receive serial data received by each data input/output pin, and convert, into parallel data, the serial data received by each input/output pin. It may be understood that each data input/output pin has corresponding parallel data when the serial data received by the data input/output pin is converted into parallel data. The serial-to-parallel circuit 102 may convert, into parallel data based on write clock signals (WCK0_t and WCK0_c), the serial data received by each data input/output pin. In an actual application, WCK0_t may be received by a WCK0_t pin, WCK0_c may be received by a WCK0_c pin, and WCK0_t and WCK0_c are configured to sample serial data received by the DQ0 to DQ15 pins, to further reduce a quantity of utilized pins in the memory, and improve test efficiency.

Correspondingly, the second input terminal of the data input/output selector 101 may receive multiple pieces of parallel data corresponding to the multiple data input/output pins. In this case, in the test mode, the data input/output selector 101 may transmit each bit of data in parallel data corresponding to the target data input/output pin to the transmission paths corresponding to the one corresponding data input/output pin; and in the working mode, the data input/output selector 101 may further separately transmit parallel data corresponding to the one corresponding data input/output pin to the transmission paths corresponding to the one corresponding data input/output pin.

In this example, as shown in FIG. 3, the serial-to-parallel circuit 102 may include multiple serial-to-parallel sub-circuits 1021, an input terminal of each of the serial-to-parallel sub-circuits 1021 is connected to one data input/output pin, and each of the serial-to-parallel sub-circuits 1021 may convert, into parallel data, serial data received by a connected data input/output pin, so that the serial data received by each data input/output pin can be converted into parallel data.

In an actual application, after converting, into parallel data, the serial data received by the connected data input/output pin, each of the serial-to-parallel sub-circuits 1021 may transmit the parallel data to one corresponding first selector, and may further transmit each bit of data in the parallel data corresponding to the target data input/output pin to each first selector. For example, the first input terminal of each of the first selectors 1011 may successively receive 1-bit data in parallel data corresponding to the target data input/output pin based on a sequence of transmitting each bit of data in multi-bit serial data received by the target data input/output pin. Therefore, each of the first selectors 1011 can receive 1-bit data in the parallel data corresponding to the target data input/output pin. This reduces a possibility of a transmission error. Similarly, the second input terminal of each of the second selectors may successively receive 1-bit data in parallel data corresponding to a corresponding data input/output pin based on a sequence of transmitting each bit of data in multi-bit serial data received by the corresponding data input/output pin. Therefore, each of the second selectors can receive 1-bit data in the parallel data corresponding to the corresponding data input/output pin. This also reduces a possibility of a data transmission error.

That the target data input/output pin is the DQ7 pin is taken as an example. The serial-to-parallel circuit converts, into 16-bit parallel data, the 16-bit serial data received by each of the DQ0 to DQ15 pins. The 16-bit parallel data of the DQ7 pin is respectively denoted as burst0 to burst15. The serial-to-parallel circuit may separately transmit the 16-bit parallel data of the DQ7 pin to each of the first selectors, and may further transmit parallel data corresponding to the DQ0 to DQ15 pins to mux0 to mux15 respectively.

With reference to FIG. 3 and FIG. 11, the first input terminal of mux0 receives burst0, and the second input terminal of mux0 receives parallel data corresponding to the DQ0 pin; the first input terminal of mux1 receives burst1, and the second input terminal of mux1 receives parallel data corresponding to the DQ1 pin; the first input terminal of mux2 receives burst2, and the second input terminal of mux2 receives parallel data corresponding to the DQ2 pin; the first input terminal of mux3 receives burst3, and the second input terminal of mux3 receives parallel data corresponding to the DQ3 pin; the first input terminal of mux4 receives burst4, and the second input terminal of mux4 receives parallel data corresponding to the DQ4 pin; the first input terminal of mux5 receives burst5, and the second input terminal of mux5 receives parallel data corresponding to the DQ5 pin; the first input terminal of mux6 receives burst6, and the second input terminal of mux6 receives parallel data corresponding to the DQ6 pin; the first input terminal of mux7 receives burst7, and the second input terminal of mux7 receives parallel data corresponding to the DQ7 pin; the first input terminal of mux8 receives burst8, and the second input terminal of mux8 receives parallel data corresponding to the DQ8 pin; the first input terminal of mux9 receives burst9, and the second input terminal of mux9 receives parallel data corresponding to the DQ9 pin; the first input terminal of mux10 receives burst10, and the second input terminal of mux10 receives parallel data corresponding to the DQ10 pin; the first input terminal of mux11 receives burst11, and the second input terminal of mux11 receives parallel data corresponding to the DQ11 pin; the first input terminal of mux12 receives burst12, and the second input terminal of mux12 receives parallel data corresponding to the DQ12 pin; the first input terminal of mux13 receives burst13, and the second input terminal of mux13 receives parallel data corresponding to the DQ13 pin; the first input terminal of mux14 receives burst14, and the second input terminal of mux14 receives parallel data corresponding to the DQ14 pin; and the first input terminal of mux15 receives burst15, and the second input terminal of mux15 receives parallel data corresponding to the DQ15 pin.

Correspondingly, in the test mode, mux0 transmits burst0 to various transmission paths corresponding to the DQ0 pin, mux1 transmits burst1 to various transmission paths corresponding to the DQ1 pin, mux2 transmits burst2 to various transmission paths corresponding to the DQ2 pin, mux3 transmits burst3 to various transmission paths corresponding to the DQ3 pin, mux4 transmits burst4 to various transmission paths corresponding to the DQ4 pin, mux5 transmits burst5 to various transmission paths corresponding to the DQ5 pin, mux6 transmits burst6 to various transmission paths corresponding to the DQ6 pin, mux7 transmits burst7 to various transmission paths corresponding to the DQ7 pin, mux8 transmits burst8 to various transmission paths corresponding to the DQ8 pin, mux9 transmits burst9 to various transmission paths corresponding to the DQ9 pin, mux10 transmits burst10 to various transmission paths corresponding to the DQ10 pin, mux11 transmits burst11 to various transmission paths corresponding to the DQ11 pin, mux12 transmits burst12 to various transmission paths corresponding to the DQ12 pin, mux13 transmits burst13 to various transmission paths corresponding to the DQ13 pin, mux14 transmits burst14 to various transmission paths corresponding to the DQ14 pin, and mux15 transmits burst15 to various transmission paths corresponding to the DQ15 pin. It should be noted that, in the test mode, each bit of data in the parallel data corresponding to the DQ7 pin is transmitted to various transmission paths corresponding to each DQ pin. In this case, data written into memory cells corresponding to the transmission paths in each DQ pin is the same.

In the working mode, each second selector in mux0 transmits 1-bit data in the parallel data corresponding to the DQ0 pin to one transmission path corresponding to the DQ0 pin; each second selector in mux1 transmits 1-bit data in the parallel data corresponding to the DQ1 pin to one transmission path corresponding to the DQ1 pin; each second selector in mux2 transmits 1-bit data in the parallel data corresponding to the DQ2 pin to one transmission path corresponding to the DQ2 pin; each second selector in mux3 transmits 1-bit data in the parallel data corresponding to the DQ3 pin to one transmission path corresponding to the DQ3 pin; each second selector in mux4 transmits 1-bit data in the parallel data corresponding to the DQ4 pin to one transmission path corresponding to the DQ4 pin; each second selector in mux5 transmits 1-bit data in the parallel data corresponding to the DQ5 pin to one transmission path corresponding to the DQ5 pin; each second selector in mux6 transmits 1-bit data in the parallel data corresponding to the DQ6 pin to one transmission path corresponding to the DQ6 pin; each second selector in mux7 transmits 1-bit data in the parallel data corresponding to the DQ7 pin to one transmission path corresponding to the DQ7 pin; each second selector in mux8 transmits 1-bit data in the parallel data corresponding to the DQ8 pin to one transmission path corresponding to the DQ8 pin; each second selector in mux9 transmits 1-bit data in the parallel data corresponding to the DQ9 pin to one transmission path corresponding to the DQ9 pin; each second selector in mux10 transmits 1-bit data in the parallel data corresponding to the DQ10 pin to one transmission path corresponding to the DQ10 pin; each second selector in mux11 transmits 1-bit data in the parallel data corresponding to the DQ11 pin to one transmission path corresponding to the DQ11 pin; each second selector in mux12 transmits 1-bit data in the parallel data corresponding to the DQ12 pin to one transmission path corresponding to the DQ12 pin; each second selector in mux13 transmits 1-bit data in the parallel data corresponding to the DQ13 pin to one transmission path corresponding to the DQ13 pin; each second selector in mux14 transmits 1-bit data in the parallel data corresponding to the DQ14 pin to one transmission path corresponding to the DQ14 pin; and each second selector in mux15 transmits 1-bit data in the parallel data corresponding to the DQ15 pin to one transmission path corresponding to the DQ15 pin.

In some embodiments, the memory may further include a latch circuit 103. As shown in FIG. 3, an input terminal of the latch circuit 103 is connected to an output terminal of the serial-to-parallel circuit 102, and an output terminal of the latch circuit 103 is connected to the multiple first selectors 1011 in the data input/output selector 101. The latch circuit 103 can receive multiple pieces of parallel data that correspond to the multiple data input/output pins and that are transmitted by the serial-to-parallel circuit 102, store the multiple pieces of parallel data corresponding to the multiple data input/output pins, transmit each of the multiple pieces of parallel data corresponding to the multiple data input/output pins to a first selector 1011 corresponding to each data input/output pin after a write command (WrCmd) received, and further separately transmit each bit of data in the parallel data corresponding to the target data input/output pin to the first selector 1011 corresponding to each data input/output pin. Therefore, each of the first selectors 1011 can receive parallel data corresponding to one data input/output pin and 1-bit data in the parallel data corresponding to the target data input/output pin.

In this example, the latch circuit 103 may store the multiple pieces of parallel data corresponding to the multiple data input/output pins, separately transmit each bit of data in parallel data corresponding to any one of the data input/output pins to the first selector 1011 corresponding to each data input/output pin after the write command is received, and separately transmit the parallel data corresponding to each data input/output pin to the first selector 1011 corresponding to the data input/output pin.

The latch circuit 103 may include multiple latch sub-circuits 1031, an input terminal of each of the latch sub-circuits 1031 is connected to one serial-to-parallel sub-circuit 1021, and an output terminal of each of the latch sub-circuits 1031 is connected to one first selector 1011. Each of the latch sub-circuits 1031 may receive parallel data output by a corresponding serial-to-parallel sub-circuit, i.e. receive parallel data corresponding to one data input/output pin. After receiving parallel data corresponding to one data input/output pin, each of the latch sub-circuits 1031 stores parallel data corresponding to a corresponding data input/output pin, and transmits the parallel data corresponding to the corresponding data input/output pin to one corresponding first selector after the write command is received. In addition, after the write command is received, a latch sub-circuit 1031 corresponding to the target data input/output pin further transmits each bit of data in the parallel data corresponding to the target data input/output pin to the first selector 1011 corresponding to each data input/output pin. Therefore, each of the first selectors 1011 can receive parallel data of a corresponding data input/output pin, and can further receive 1-bit data in the parallel data corresponding to the target data input/output pin.

In this example, as shown in FIG. 4, each of the latch sub-circuits 1031 may include multiple latches 1032, each of the latches 1032 is connected to one of the second selectors 1012, each of the second selectors 1012 corresponds to one transmission path, and each latch corresponding to the target data input/output pin may be further connected to multiple second selectors. Each of the latch sub-circuits 1031 may receive parallel data corresponding to one data input/output pin, and each of the latches 1032 may receive 1-bit data in parallel data corresponding to one data input/output pin. After receiving the write command, each of the latches 1032 may transmit 1-bit data in parallel data of a corresponding data input/output pin to a connected second selector 1012. In addition, after receiving the write command, each latch 1032 corresponding to the target data input/output pin may not only transmit 1-bit data in the parallel data corresponding to the target data input/output pin to a second selector corresponding to the target data input/output pin, but also transmit 1-bit data in the parallel data corresponding to the target data input/output pin to multiple second selectors 1012 corresponding to one data input/output pin. Therefore, each of the second selectors 1012 can not only receive 1-bit data in parallel data of a corresponding data input/output pin, but also receive 1-bit data in the parallel data corresponding to the target data input/output pin.

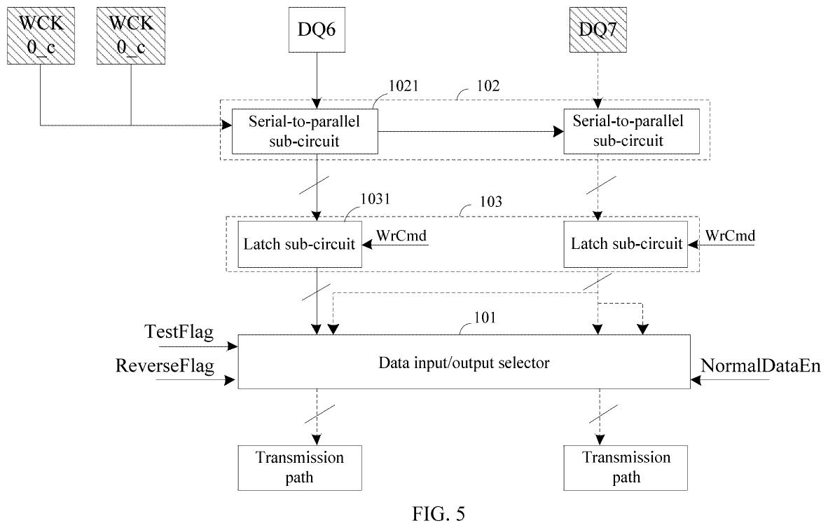

FIG. 5 is an example structural diagram of a memory according to an embodiment of the present disclosure. The memory provided in this embodiment is configured to reduce a quantity of utilized pins of the memory in a test process. As shown in FIG. 5, the memory includes multiple data input/output pins (only two data input/output pins, i.e. DQ6 and DQ7 pins, are shown in FIG. 5) and a data input/output selector 101. One of the data input/output pins is a target data input/output pin (for example, DQ7 is the target data input/output pin).

The multiple data input/output pins are configured to receive or output working serial data when the memory is in a working mode, and the target data input/output pin is configured to receive test serial data when the memory is in a test mode. A first input terminal of the data input/output selector 101 receives, when the memory is in the test mode, the test serial data received by the target data input/output pin. A second input terminal of the data input/output selector 101 receives, when the memory is in the working mode, the working serial data received by the multiple data input/output pins. A first control terminal of the data input/output selector 101 receives a test enable signal group TestFlag. A second control terminal of the data input/output selector 101 receives a reverse enable signal group ReverseFlag. A third control terminal of the data input/output selector 101 receives a working enable signal NormalDataEn. When the memory is in the test mode, the data input/output selector 101 is configured to separately transmit data in the test serial data to a part of transmission paths corresponding to the one corresponding data input/output pin based on the test enable signal group TestFlag, and the data input/output selector 101 is further configured to separately transmit, to another part of transmission paths corresponding to the one corresponding data input/output pin based on the reverse enable signal group ReverseFlag, reverse data generated after reversing data in the test serial data. When the memory is in the working mode, the data input/output selector 101 transmits, to respective corresponding transmission paths based on the working enable signal NormalDataEn, working serial data received by various data input/output pins.

Therefore, during a test, the memory may receive the test serial data only through the target data input/output pin, so that a quantity of utilized data input/output pins is reduced, thereby increasing a quantity of simultaneously tested memories, and improving test efficiency. In addition, the data in the test serial data and the reverse data generated after reversing the data in the test serial data can be transmitted to the transmission paths corresponding to various data input/output pins, to expand a data pattern, and increase a test coverage, for example, may be utilized for an error correcting code (ECC) test.

The transmission path corresponding to the data input/output pin includes a path for writing, into a memory cell, e.g. the data transmission circuit and the array read/write circuit in the foregoing embodiment, working serial data or test serial data received by the data input/output pin. Because each data input/output pin may receive multi-bit serial data, only 1-bit data can be written into each memory cell, and serial data received by each data input/output pin may be written into multiple memory cells, each data input/output pin may correspond to multiple transmission paths.

In an actual application, the memory provided in this embodiment may be applied to tests of various memory chips. For example, the memory may be applied to, including but not limited to, a low power double data rate synchronous dynamic random access memory (LPDDR SDRAM), e.g., LPDDR5. The memory in this embodiment may be considered as a device under test (DUT).

In some embodiments, all transmission paths corresponding to any one of the data input/output pins receive the same bit of data in the test serial data, i.e. each bit of data in the test serial data received by the target data input/output pin may be separately transmitted to all transmission paths corresponding to one corresponding data input/output pin. Therefore, only one data input/output pin is required to receive the test serial data during a memory test, thereby reducing a quantity of utilized pins.

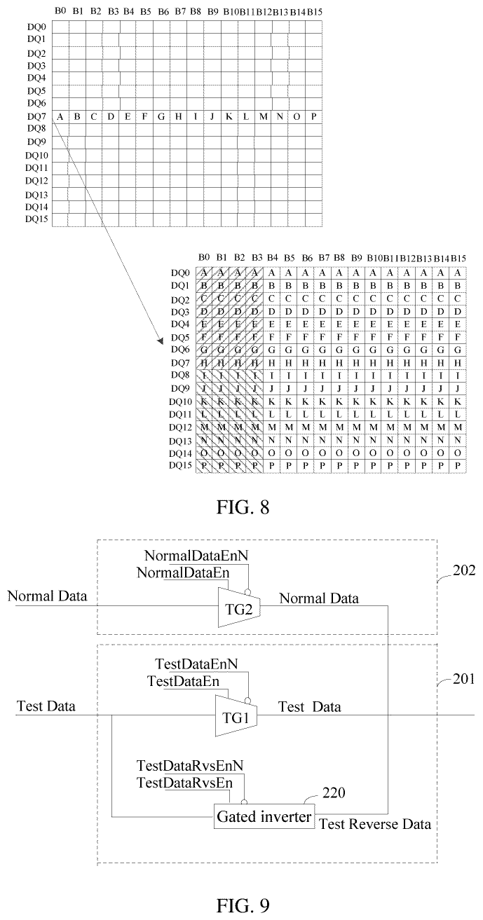

For example, the memory includes 16 DQ pins, which are respectively denoted as DQ0 to DQ15 pins. The DQ7 pin is the target data input/output pin, and the test serial data received by the DQ7 pin is 16-bit data, which is respectively denoted as A to P. As shown in FIG. 8, all transmission paths corresponding to the DQ0 pin may receive A, all transmission paths corresponding to the DQ1 pin may receive B, all transmission paths corresponding to the DQ2 pin may receive C, all transmission paths corresponding to the DQ3 pin may receive D, all transmission paths corresponding to the DQ4 pin may receive E, all transmission paths corresponding to the DQ5 pin may receive F, all transmission paths corresponding to the DQ6 pin may receive G, all transmission paths corresponding to the DQ7 pin may receive H, all transmission paths corresponding to the DQ8 pin may receive I, all transmission paths corresponding to the DQ9 pin may receive J, all transmission paths corresponding to the DQ10 pin may receive K, all transmission paths corresponding to the DQ11 pin may receive L, all transmission paths corresponding to the DQ12 pin may receive M, all transmission paths corresponding to the DQ13 pin may receive N, all transmission paths corresponding to the DQ14 pin may receive O, and all transmission paths corresponding to the DQ15 pin may receive P. Certainly, all transmission paths corresponding to any one of the data input/output pins may also receive reverse data of 1-bit data in the test serial data, or a part of transmission paths receive 1-bit data in the test serial data, and the remaining transmission paths receive reverse data of 1-bit data in the test serial data.

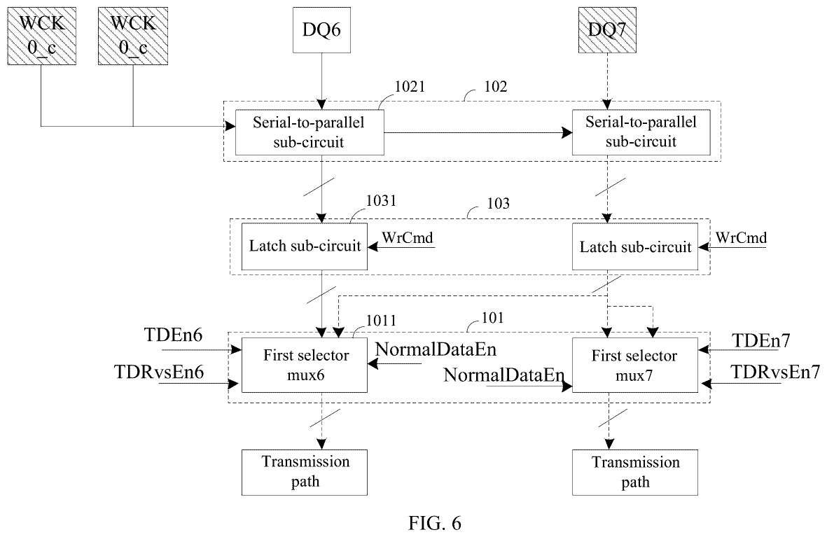

In some embodiments, as shown in FIG. 6, the data input/output selector 101 includes multiple first selectors 1011, each of the first selectors 1011 corresponds to one data input/output pin, a first input terminal of each of the first selectors 1011 receives 1-bit data in the test serial data when the memory is in the test mode, and a second input terminal of each of the first selectors 1011 receives, when the memory is in the working mode, working serial data received by a corresponding data input/output pin. The test enable signal group TestFlag includes multiple test enable signals TDEn0 to TDEn15, and the reverse enable signal group ReverseFlag includes multiple reverse enable signals TDRvsEn0 to TDRvsEn15. A first control terminal of each of the first selectors receives one of the test enable signals, a second control terminal of each of the first selectors receives one of the reverse enable signals, and a third control terminal of each of the first selectors receives the working enable signal NormalDataEn. For example, the data input/output selector 101 includes 16 first selectors, each of the first selectors corresponds to one data input/output pin, first control terminals of the 16 first selectors successively receive the test enable signals TDEn0 to TDEn15, second control terminals of the 16 first selectors successively receive the reverse enable signals TDRvsEn0 to TDRvsEn15, and third control terminals of the 16 first selectors all receive the working enable signal NormalDataEn.

It should be noted that different first selectors may receive different test enable signals, different first selectors may also receive different reverse enable signals, and different first selectors receive the same working enable signal. Certainly, different first selectors may receive the same test enable signal and the same reverse enable signal.

When the memory is in the test mode, each of the first selectors may transmit, to a part of transmission paths corresponding to a data input/output pin corresponding to the first selector based on the test enable signal received by the first control terminal of the first selector, data received by the first input terminal of the first selector, and each of the first selectors is further configured to transmit, to another part of transmission paths corresponding to the data input/output pin corresponding to the first selector based on the reverse enable signal received by the second control terminal of the first selector, reverse data generated after reversing the data received by the first input terminal of the first selector. All transmission paths corresponding to the data input/output pin include the part of transmission paths and the another part of transmission paths. When the memory is in the working mode, each of the first selectors may transmit, to transmission paths corresponding to the corresponding data input/output pin based on the working enable signal received by the third control terminal of the first selector, the working serial data that is of the corresponding data input/output pin and that is received by the second input terminal of the first selector.

For example, as shown in FIG. 6, FIG. 6 shows only the DQ6 pin and the DQ7 pin. It may be understood that the memory includes but is not limited to the DQ6 pin and the DQ7 pin. The memory may include 16 DQ pins in total, which are the DQ0 to DQ15 pins. The data input/output selector may include 16 first selectors, and the 16 first selectors are marked as mux0 to mux15. The DQ0 pin corresponds to mux0, the DQ1 pin corresponds to mux1, the DQ2 pin corresponds to mux2, the DQ3 pin corresponds to mux3, and so on, until the DQ15 pin corresponds to mux15. The DQ7 pin is the target data input/output pin, and the test serial data received by the DQ7 pin is 16-bit data, which is respectively denoted as A to P.

A first input terminal of mux0 receives A when the memory is in the test mode, and a second input terminal of mux0 receives, when the memory is in the working mode, working serial data received by the DQ0 pin. A first input terminal of mux1 receives B when the memory is in the test mode, and a second input terminal of mux1 receives, when the memory is in the working mode, working serial data received by the DQ1 pin. A first input terminal of mux2 receives C when the memory is in the test mode, and a second input terminal of mux2 receives, when the memory is in the working mode, working serial data received by the DQ2 pin. A first input terminal of mux3 receives D when the memory is in the test mode, and a second input terminal of mux3 receives, when the memory is in the working mode, working serial data received by the DQ3 pin. A first input terminal of mux4 receives E when the memory is in the test mode, and a second input terminal of mux4 receives, when the memory is in the working mode, working serial data received by the DQ4 pin. A first input terminal of mux5 receives F when the memory is in the test mode, and a second input terminal of mux5 receives, when the memory is in the working mode, working serial data received by the DQ5 pin. A first input terminal of mux6 receives G when the memory is in the test mode, and a second input terminal of mux6 receives, when the memory is in the working mode, working serial data received by the DQ6 pin. A first input terminal of mux7 receives H when the memory is in the test mode, and a second input terminal of mux7 receives, when the memory is in the working mode, working serial data received by the DQ7 pin. A first input terminal of mux8 receives I when the memory is in the test mode, and a second input terminal of mux8 receives, when the memory is in the working mode, working serial data received by the DQ8 pin. A first input terminal of mux9 receives J when the memory is in the test mode, and a second input terminal of mux9 receives, when the memory is in the working mode, working serial data received by the DQ9 pin. A first input terminal of mux10 receives K when the memory is in the test mode, and a second input terminal of mux10 receives, when the memory is in the working mode, working serial data received by the DQ10 pin. A first input terminal of mux11 receives L when the memory is in the test mode, and a second input terminal of mux11 receives, when the memory is in the working mode, working serial data received by the DQ11 pin. A first input terminal of mux12 receives M when the memory is in the test mode, and a second input terminal of mux12 receives, when the memory is in the working mode, working serial data received by the DQ12 pin. A first input terminal of mux13 receives N when the memory is in the test mode, and a second input terminal of mux13 receives, when the memory is in the working mode, working serial data received by the DQ13 pin. A first input terminal of mux14 receives O when the memory is in the test mode, and a second input terminal of mux14 receives, when the memory is in the working mode, working serial data received by the DQ14 pin. A first input terminal of mux15 receives P when the memory is in the test mode, and a second input terminal of mux15 receives, when the memory is in the working mode, working serial data received by the DQ15 pin.

Correspondingly, when the memory is in the test mode, mux0 transmits A to a part of transmission paths corresponding to the DQ0 pin based on the test enable signal TDEn0 received by the first control terminal of mux0, and transmits, to another part of transmission paths corresponding to the DQ0 pin based on the reverse enable signal TDRvsEn0 received by the second control terminal of mux0, reverse data generated after reversing A. mux1 transmits B to a part of transmission paths corresponding to the DQ1 pin based on the test enable signal TDEn1 received by the first control terminal of mux1, and transmits, to another part of transmission paths corresponding to the DQ1 pin based on the reverse enable signal TDRvsEn1 received by the second control terminal of mux1, reverse data generated after reversing B. mux2 transmits C to a part of transmission paths corresponding to the DQ2 pin based on the test enable signal TDEn2 received by the first control terminal of mux2, and transmits, to another part of transmission paths corresponding to the DQ2 pin based on the reverse enable signal TDRvsEn2 received by the second control terminal of mux2, reverse data generated after reversing C. mux3 transmits D to a part of transmission paths corresponding to the DQ3 pin based on the test enable signal TDEn3 received by the first control terminal of mux3, and transmits, to another part of transmission paths corresponding to the DQ3 pin based on the reverse enable signal TDRvsEn3 received by the second control terminal of mux3, reverse data generated after reversing D. mux4 transmits E to a part of transmission paths corresponding to the DQ4 pin based on the test enable signal TDEn4 received by the first control terminal of mux4, and transmits, to another part of transmission paths corresponding to the DQ4 pin based on the reverse enable signal TDRvsEn4 received by the second control terminal of mux4, reverse data generated after reversing E. mux5 transmits F to a part of transmission paths corresponding to the DQ5 pin based on the test enable signal TDEn5 received by the first control terminal of mux5, and transmits, to another part of transmission paths corresponding to the DQ5 pin based on the reverse enable signal TDRvsEn5 received by the second control terminal of mux5, reverse data generated after reversing F. mux6 transmits G to a part of transmission paths corresponding to the DQ6 pin based on the test enable signal TDEn6 received by the first control terminal of mux6, and transmits, to another part of transmission paths corresponding to the DQ6 pin based on the reverse enable signal TDRvsEn6 received by the second control terminal of mux6, reverse data generated after reversing G. mux7 transmits H to a part of transmission paths corresponding to the DQ7 pin based on the test enable signal TDEn7 received by the first control terminal of mux7, and transmits, to another part of transmission paths corresponding to the DQ7 pin based on the reverse enable signal TDRvsEn7 received by the second control terminal of mux7, reverse data generated after reversing H. mux8 transmits I to a part of transmission paths corresponding to the DQ8 pin based on the test enable signal TDEn8 received by the first control terminal of mux8, and transmits, to another part of transmission paths corresponding to the DQ8 pin based on the reverse enable signal TDRvsEn8 received by the second control terminal of mux8, reverse data generated after reversing I. mux9 transmits J to a part of transmission paths corresponding to the DQ9 pin based on the test enable signal TDEn9 received by the first control terminal of mux9, and transmits, to another part of transmission paths corresponding to the DQ9 pin based on the reverse enable signal TDRvsEn9 received by the second control terminal of mux9, reverse data generated after reversing J. mux10 transmits K to a part of transmission paths corresponding to the DQ10 pin based on the test enable signal TDEn10 received by the first control terminal of mux10, and transmits, to another part of transmission paths corresponding to the DQ10 pin based on the reverse enable signal TDRvsEn10 received by the second control terminal of mux10, reverse data generated after reversing K. mux11 transmits L to a part of transmission paths corresponding to the DQ11 pin based on the test enable signal TDEn11 received by the first control terminal of mux11, and transmits, to another part of transmission paths corresponding to the DQ11 pin based on the reverse enable signal TDRvsEn11 received by the second control terminal of mux11, reverse data generated after reversing L. mux12 transmits M to a part of transmission paths corresponding to the DQ12 pin based on the test enable signal TDEn12 received by the first control terminal of mux12, and transmits, to another part of transmission paths corresponding to the DQ12 pin based on the reverse enable signal TDRvsEn12 received by the second control terminal of mux12, reverse data generated after reversing M. mux13 transmits N to a part of transmission paths corresponding to the DQ13 pin based on the test enable signal TDEn13 received by the first control terminal of mux13, and transmits, to another part of transmission paths corresponding to the DQ13 pin based on the reverse enable signal TDRvsEn13 received by the second control terminal of mux13, reverse data generated after reversing N. mux14 transmits O to a part of transmission paths corresponding to the DQ14 pin based on the test enable signal TDEn14 received by the first control terminal of mux14, and transmits, to another part of transmission paths corresponding to the DQ14 pin based on the reverse enable signal TDRvsEn14 received by the second control terminal of mux14, reverse data generated after reversing O. mux15 transmits P to a part of transmission paths corresponding to the DQ15 pin based on the test enable signal TDEn15 received by the first control terminal of mux15, and transmits, to another part of transmission paths corresponding to the DQ15 pin based on the reverse enable signal TDRvsEn15 received by the second control terminal of mux15, reverse data generated after reversing P.

It should be noted that, when the memory is in the test mode, mux0 alternatively transmits A to all transmission paths corresponding to the DQ0 pin based on the test enable signal TDEn0 received by the first control terminal of mux0, or transmits, to all transmission paths corresponding to the DQ0 pin based on the reverse enable signal TDRvsEn0 received by the second control terminal of mux0, reverse data generated after reversing A. Other muxes may alternatively transmit corresponding data to all transmission paths of corresponding DQ pins based on the test enable signals TDEn received by the first control terminals of the muxes, or transmit corresponding data to all transmission paths of corresponding DQ pins based on the reverse enable signals TDRvsEn received by the second control terminals of the muxes. Details are not described herein again.

When the memory is in the working mode, mux0 transmits, to transmission paths corresponding to the DQ0 pin, the working serial data received by the DQ0 pin; mux1 transmits, to transmission paths corresponding to the DQ1 pin, the working serial data received by the DQ1 pin; mux2 transmits, to transmission paths corresponding to the DQ2 pin, the working serial data received by the DQ2 pin; mux3 transmits, to transmission paths corresponding to the DQ3 pin, the working serial data received by the DQ3 pin; mux4 transmits, to transmission paths corresponding to the DQ4 pin, the working serial data received by the DQ4 pin; mux5 transmits, to transmission paths corresponding to the DQ5 pin, the working serial data received by the DQ5 pin; mux6 transmits, to transmission paths corresponding to the DQ6 pin, the working serial data received by the DQ6 pin; mux7 transmits, to transmission paths corresponding to the DQ7 pin, the working serial data received by the DQ7 pin; mux8 transmits, to transmission paths corresponding to the DQ8 pin, the working serial data received by the DQ8 pin; mux9 transmits, to transmission paths corresponding to the DQ9 pin, the working serial data received by the DQ9 pin; mux10 transmits, to transmission paths corresponding to the DQ10 pin, the working serial data received by the DQ10 pin; mux11 transmits, to transmission paths corresponding to the DQ11 pin, the working serial data received by the DQ11 pin; mux12 transmits, to transmission paths corresponding to the DQ12 pin, the working serial data received by the DQ12 pin; mux13 transmits, to transmission paths corresponding to the DQ13 pin, the working serial data received by the DQ13 pin; mux14 transmits, to transmission paths corresponding to the DQ14 pin, the working serial data received by the DQ14 pin; and mux15 transmits, to transmission paths corresponding to the DQ15 pin, the working serial data received by the DQ15 pin.

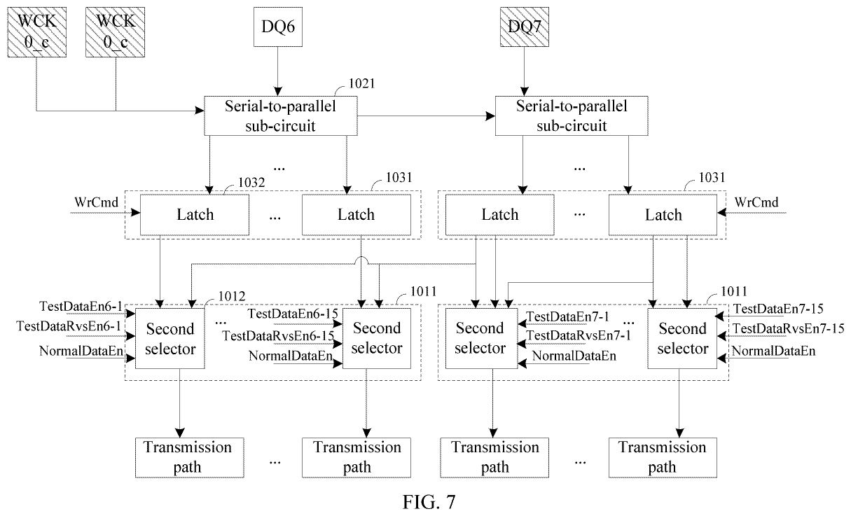

In this example, as shown in FIG. 7, each of the first selectors 1011 includes multiple second selectors 1012, and each of the second selectors 1012 corresponds to one transmission path of one data input/output pin. A first input terminal of each of second selectors 1012 in the same first selector 1011 receives 1-bit data in the test serial data when the memory is in the test mode, and a second input terminal receives, when the memory is in the working mode, 1-bit data in the working serial data received by a corresponding data input/output pin. The test enable signal TDEn includes multiple test enable sub-signals TestDataEn, and the reverse enable signal TDRvsEn includes multiple reverse enable sub-signals TestDataRvsEn. A first control terminal of each second selector 1012 receives one of the test enable sub-signals TestDataEn, a second control terminal receives one of the reverse enable sub-signals TestDataRvsEn, and a third control terminal receives the working enable signal NormalDataEn.

For example, as shown in FIG. 7, the first selector mux6 corresponding to the DQ6 pin includes 16 second selectors, first terminals of the second selectors in mux6 successively receive test enable sub-signals TestDataEn6-0 to TestDataEn6-15, and second terminals of the second selectors in mux6 successively receive reverse enable sub-signals TestDataRvsEn6-0 to TestDataRvsEn6-15. The first selector mux7 corresponding to the DQ7 pin includes 16 second selectors, first terminals of the second selectors in mux7 successively receive test enable sub-signals TestDataEn7-0 to TestDataEn7-15, and second terminals of the second selector in mux7 successively receive reverse enable sub-signals TestDataRvsEn7-0 to TestDataRvsEn7-15.

It should be noted that second selectors in different first selectors may receive different test enable sub-signals TestDataEn and different reverse enable sub-signals TestDataRvsEn, or second selectors in the same first selector may receive different test enable sub-signals TestDataEn and different reverse enable sub-signals TestDataRvsEn. The second selectors in the same first selector may alternatively receive the same test enable sub-signal TestDataEn and the same reverse enable sub-signal TestDataRvsEn.

It may be understood that data corresponding to any one of multiple transmission paths corresponding to each of the DQ0 to DQ15 pins may be reversed. When the data is reversed, the data may be repeatedly reversed per 2 bits, 4 bits, or 8 bits, i.e. 2-bit data, 4-bit data, or 8-bit data at the same locations in data transmission paths corresponding to each DQ pin is reversed.

For example, as shown in FIG. 8, 16 second selectors corresponding to each of the DQ0 to DQ7 pins are controlled by four groups of same reverse enable sub-signals TestDataRvsL<0-3>, TestDataRvsL<4-7>, TestDataRvsL<8-11>, and TestDataRvsL<12-15>, i.e. TestDataRvsL<0-3>, TestDataRvsL<4-7>, TestDataRvsL<8-11>, and TestDataRvsL<12-15> are the same reverse enable sub-signals, and 16 second selectors corresponding to each of the DQ8 to DQ15 pins are controlled by four groups of same reverse enable sub-signals TestDataRvsR<0-3>, TestDataRvsR<4-7>, TestDataRvsR<8-11>, and TestDataRvsR<12-15>, i.e. TestDataRvsR<0-3>, TestDataRvsR<4-7>, TestDataRvsR<8-11>, and TestDataRvsR<12-15> are the same reverse enable sub-signals.

TestDataRvsL<0-3> is configured to control B0 to B3 in the DQ0 to DQ7 pins to be reversed, TestDataRvsL<4-7> is configured to control B4 to B7 in the DQ0 to DQ7 pins to be reversed, TestDataRvsL<8-11> is configured to control B8 to B11 in the DQ0 to DQ7 pins to be reversed, and TestDataRvsL<12-15> is configured to control B12 to B15 in the DQ0 to DQ7 pins to be reversed. TestDataRvsR<0-3> is configured to control B0 to B3 in the DQ8 to DQ15 pins to be reversed, TestDataRvsR<4-7> is configured to control B4 to B7 in the DQ8 to DQ15 pins to be reversed, TestDataRvsR<8-11> is configured to control B8 to B11 in the DQ8 to DQ15 pins to be reversed, and TestDataRvsR<12-15> is configured to control B12 to B15 in the DQ8 to DQ15 pins to be reversed.

It may be understood that, in this example, when there is no reverse function, data transmitted on transmission paths corresponding to each DQ pin is consistent. In this case, only 16 pieces of data are independent. Therefore, there are a total of 2\hat{ }16 data combinations. When there is a reverse function, 16 pieces of data corresponding to each DQ pin are independent, and eight reverse enable sub-signals TestDataRvsEn control data to be reversed. Therefore, there are a total of 2\hat{ }24 data combinations.

When the memory is in the test mode, each second selector is configured to transmit, to one transmission path corresponding to the second selector based on the test enable sub-signal TestDataEn received by the first control terminal of the second selector, data received by the first input terminal of the second selector, or each second selector is configured to transmit, to one transmission path corresponding to the second selector based on the reverse enable sub-signal TestDataRvsEn received by the second control terminal of the second selector, reverse data generated after reversing data received by the first input terminal of the second selector. When the memory is in the working mode, each second selector is configured to transmit, to a transmission path corresponding to the second selector based on the working enable signal NormalDataEn received by the third control terminal of the second selector, data received by the second input terminal of the second selector. In this embodiment, one transmission path of the data input/output pin may be understood as a transmission path for writing, into one memory cell, 1-bit data in test serial data or working serial data received by the data input/output pin.

In this example, as shown in FIG. 7, taking the DQ6 pin and the DQ7 pin as examples, the DQ7 pin is the target data input/output pin, and the DQ7 pin and the DQ6 pin each correspond to multiple second selectors 1012. For example, when the DQ6 pin and the DQ7 pin each correspond to 16 transmission paths, the DQ6 pin and the DQ7 pin each may correspond to 16 second selectors. First input terminals of the second selectors corresponding to the DQ7 pin receive, when the memory is in the test mode, the same bit of data in test serial data received by the DQ7 pin, and second input terminals separately receive, when the memory is in the working mode, 1-bit data in working serial data received by the DQ7 pin. First input terminals of the second selectors corresponding to the DQ6 pin receive, when the memory is in the test mode, the same bit of data in test serial data received by the DQ7 pin, and second input terminals separately receive, when the memory is in the working mode, 1-bit data in working serial data received by the DQ6 pin.

In some embodiments, as shown in FIG. 9, the second selector includes a first control circuit 201 and a second control circuit 202. For the first control circuit 201, an input terminal of the first control circuit receives 1-bit data (Test Data) in the test serial data when the memory is in the test mode, a first control terminal of the first control circuit receives the test enable sub-signal TestDataEn, and a second control terminal of the first control circuit receives the reverse enable sub-signal TestDataRvsEn. The first control circuit 201 is configured to transmit, to the transmission path corresponding to the second selector based on the test enable sub-signal TestDataEn, the data (Test Data) received by the input terminal of the first control circuit, or transmit, to the transmission path corresponding to the second selector based on the reverse enable sub-signal TestDataRvsEn, reverse data generated after reversing the data received by the input terminal of the first control circuit, i.e. transmit, to the transmission path corresponding to the second selector, the reverse data (Test Reverse Data) of the data received by the input terminal of the first control circuit. For the second control circuit 202, an input terminal of the second control circuit receives, when the memory is in the working mode, 1-bit data (Normal Data) in working serial data received by a corresponding data input/output pin, and a control terminal of the second control circuit receives the working enable signal NormalDataEn. The second control circuit 202 is configured to transmit, to the transmission path corresponding to the second selector based on the working enable signal NormalDataEn, the data (Normal Data) received by the input terminal of the second control circuit.

In this example, as shown in FIG. 9, the first control circuit 201 includes a first transmission gate TG1 and a gated inverter 220. An input terminal of the first transmission gate TG1 serves as the input terminal of the first control circuit 201 to receive 1-bit data (Test Data) in the test serial data when the memory is in the test mode. A first control terminal of the first transmission gate 210 serves as the first control terminal of the first control circuit 201 to receive the test enable sub-signal TestDataEn. A second control terminal of the first transmission gate TG1 receives an inverted signal TestDataEnN of the test enable sub-signal. An output terminal of the first transmission gate TG1 serves as an output terminal of the first control circuit 201. The first transmission gate TG1 is configured to transmit, to the transmission path corresponding to the second selector based on the test enable sub-signal TestDataEn and the inverted signal TestDataEnN of the test enable sub-signal, data received by the input terminal of the first transmission gate. An input terminal of the gated inverter 220 serves as the input terminal of the first control circuit 201 to receive 1-bit data in the test serial data when the memory is in the test mode. A first control terminal of the gated inverter 220 serves as the second control terminal of the first control circuit 201 to receive the reverse enable sub-signal TestDataRvsEn. A second control terminal of the gated inverter 220 receives an inverted signal TestDataRvsEnN of the reverse enable sub-signal. An output terminal of the gated inverter 220 serves as the output terminal of the first control circuit 201. The gated inverter 220 is configured to transmit, to the transmission path corresponding to the second selector based on the reverse enable sub-signal TestDataRvsEn and the inverted signal TestDataRvsEnN of the reverse enable sub-signal, reverse data generated after reversing data received by the input terminal of the gated inverter. The gated inverter 220 includes: a first P-type transistor MP1, where a source of the first P-type transistor MP1 is connected to a supply voltage terminal VDD, and a gate of the first P-type transistor MP1 serves as the input terminal of the gated inverter 220; a second P-type transistor MP2, where a source of the second P-type transistor is connected to a drain of the first P-type transistor MP1, a gate of the second P-type transistor serves as the first control terminal of the gated inverter to receive the reverse enable sub-signal TestDataRvsEn, and a drain of the second P-type transistor is connected to the transmission path corresponding to the second selector; a first N-type transistor MN1, where a source of the first N-type transistor MN1 is grounded, and a gate of the first N-type transistor MN1 is connected to the gate of the first P-type transistor MP1; and a second N-type transistor MN2, where a source of the second N-type transistor MN2 is connected to a drain of the first N-type transistor MN1, a gate of the second N-type transistor MN2 serves as the second control terminal of the gated inverter to receive the inverted signal TestDataRvsEnN of the reverse enable sub-signal, and a drain of the second N-type transistor MN2 is connected to a second node N2.

The second control circuit 202 includes a second transmission gate TG2. An input terminal of the second transmission gate TG2 serves as the input terminal of the second control circuit 202 to receive, when the memory is in the working mode, 1-bit data (Normal Data) in working serial data received by a corresponding data input/output pin. A first control terminal of the second transmission gate TG2 serves as the control terminal of the second control circuit 202 to receive the working enable signal NormalDataEn. A second control terminal of the second transmission gate TG2 receives an inverted signal NormalDataEnN of the working enable signal. An output terminal of the second transmission gate TG2 serves as an output terminal of the second control circuit 202. The second transmission gate TG2 is configured to transmit, to the transmission path corresponding to the second selector based on the working enable signal NormalDataEn and the inverted signal NormalDataEnN of the working enable signal, data received by the input terminal of the second transmission gate.

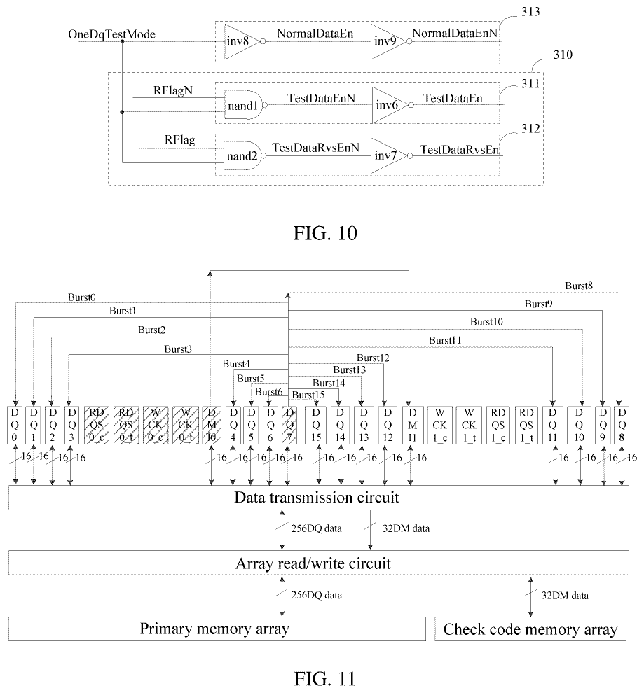

In some embodiments, as shown in FIG. 10, the memory further includes a first signal generation circuit 313. A first input terminal of the first signal generation circuit 313 receives a test indication signal OneDqTestMode. The first signal generation circuit is configured to generate the working enable signal NormalDataEn and the inverted signal NormalDataEnN of the working enable signal based on the test indication signal. The working enable signal NormalDataEn and the test indication signal OneDqTestMode are mutually inverted signals.

The memory further includes multiple second signal generation circuits 310. A first input terminal of each of the second signal generation circuits 310 receives one test indication signal OneDqTestMode. A second input terminal of each of the second signal generation circuits 310 receives one reverse indication sub-signal RFlag. An output terminal of each of the second signal generation circuits 310 is connected to at least a first control terminal and a second control terminal of one of the second selectors. Each of the second signal generation circuits 310 is configured to generate the reverse enable sub-signal TestDataRvsEn, the inverted signal TestDataRvsEnN of the reverse enable sub-signal, the test enable sub-signal TestDataEn, and the invert signal TestDataEn of the test enable sub-signal based on the test indication signal OneDqTestMode and the reverse indication sub-signal RFlag. A reverse enable sub-signal TestDataRvsEn and a test enable sub-signal TestDataEn generated by the same second signal generation circuit 310 are mutually inverted signals. It should be noted that the output terminal of the second signal generation circuit may include a first output terminal and a second output terminal, the first output terminal is connected to the first control terminal of the second selector, and the second output terminal is connected to the second control terminal of the second selector.

When an output terminal of one second signal generation circuit is connected to a first control terminal and a second control terminal of one second selector, each second signal generation circuit corresponds to one second selector. In this case, reverse enable sub-signals of different second selectors may be the same or different, and working enable signals of different second selectors may be the same or different. When an output terminal of one second signal generation circuit is connected to first control terminals and second control terminals of multiple second selectors, the second signal generation circuit corresponds to multiple second selectors, and the multiple second selectors receive the same working enable signal and the same reverse enable signal. Therefore, optionally, for data that needs to be reversed, first control terminals and second control terminals of multiple corresponding second selectors thereof may be connected to the same second signal generation circuit; for data that does not need to be reversed, first control terminals and second control terminals of multiple corresponding second selectors thereof may alternatively be connected to another second signal generation circuit. Further optionally, for data that needs to be reversed, a part of second selectors in multiple corresponding second selectors thereof may be connected to the same second signal generation circuit, and the remaining second selectors in the multiple corresponding second selectors thereof may be connected to another second signal generation circuit.

In this embodiment, as shown in FIG. 10, the second signal generation circuit 310 may include a first sub-circuit 311 and a second sub-circuit 312. A first input terminal of the first sub-circuit 311 receives the test indication signal OneDqTestMode, and a second input terminal of the first sub-circuit 311 receives the inverted signal RFlagN of the reverse indication sub-signal. The first sub-circuit 311 is configured to generate the test enable sub-signal TestDataEn and the inverted signal TestDataEnN of the test enable sub-signal based on the inverted signal RFlagN of the reverse indication signal and the test indication signal OneDqTestMode. A first input terminal of the second sub-circuit 312 receives the test indication signal OneDqTestMode, and a second input terminal of the second sub-circuit receives the reverse indication sub-signal RFlag. The second sub-circuit is configured to generate the reverse enable sub-signal TestDataRvsEn and the inverted signal TestDataRvsEnN of the reverse enable sub-signal based on the reverse indication sub-signal RFlag and the test indication signal OneDqTestMode.

For example, the first sub-circuit 311 includes a first NAND gate nand1 and a sixth NOT gate inv6. A first input terminal of the first NAND gate nand1 serves as the first input terminal of the first sub-circuit 311 to receive the test indication signal OneDqTestMode. A second input terminal of the first NAND gate nand1 serves as the second input terminal of the first sub-circuit 311 to receive the inverted signal RFlagN of the reverse indication sub-signal. An output terminal of the first NAND gate nand1 outputs the inverted signal TestDataEnN of the test enable sub-signal. An input terminal of the sixth NOT gate inv6 is connected to the output terminal of the first NAND gate nand1 to receive the inverted signal TestDataEnN of the test enable sub-signal and output the test enable sub-signal TestDataEn.

The second sub-circuit 312 includes a second NAND gate nand2 and a seventh NOT gate inv7. A first input terminal of the second NAND gate nand2 serves as the first input terminal of the second sub-circuit 312 to receive the test indication signal OneDqTestMode. A second input terminal of the second NAND gate nand2 serves as the second input terminal of the second sub-circuit 312 to receive the reverse indication sub-signal RFlag. An output terminal of the second NAND gate nand2 outputs the inverted signal TestDataRvsEnN of the reverse enable sub-signal. An input terminal of the seventh NOT gate inv7 is connected to the output terminal of the second NAND gate nand2 to receive the inverted signal TestDataRvsEnN of the reverse enable sub-signal and output the reverse enable sub-signal TestDataRvsEnN.

The first signal generation circuit 313 may include an eighth NOT gate inv8 and a ninth NOT gate inv9. An input terminal of the eighth NOT gate inv8 receives the test indication signal OneDqTestMode. An output terminal of the eighth NOT gate inv8 outputs the working enable signal NormalDataEn. An input terminal of the ninth NOT gate inv9 is connected to the output terminal of the eighth NOT gate inv8 to receive the working enable signal NormalDataEn and output the inverted signal NormalDataEnN of the working enable signal.

In this example, the memory may further include a third signal generation circuit, and an input terminal of the third signal generation circuit receives the reverse indication sub-signal RFlag and outputs the inverted signal RFlagN of the reverse indication sub-signal. For example, the third signal generation circuit may include a ninth NOT gate, an input terminal of the ninth NOT gate serves as the input terminal of the third signal generation circuit, and an output terminal of the ninth NOT gate serves as an output terminal of the third signal generation circuit.

In an actual application, during a write operation, the memory transmits data to one memory cell through one bit line, and only 1 bit can be written into one memory cell when data is written into the memory cell in the memory. For example, when data needs to be written into a memory cell, e.g. 1, a word line of a row in which the memory cell is located may be selected through a row decoder, to control a transistor M in the memory cell to be conducted. A logical level of the bit line is set to 1, so that a capacitor C is charged, i.e. 1 is written into the memory cell. On the contrary, if 0 is to be written, the logical level of the bit line is set to 0, so that the capacitor C is discharged, i.e. 0 is written to the memory cell.

Therefore, when the serial data received by the data input/output pin is written into the memory cell, the multi-bit serial data received by the data input/output pin may be first converted into multiple pieces of 1-bit parallel data, and the multi-bit serial data received by the data input/output pin is separately written into different memory cells at the same time through different bit lines in one write operation.

In some embodiments, the memory may include a serial-to-parallel circuit 102. As shown in FIG. 5, an input terminal of the serial-to-parallel circuit 102 is connected to the multiple data input/output pins. The serial-to-parallel circuit 102 may include a first input terminal and a second input terminal. The first input terminal receives, when the memory is in the test mode, the test serial data received by the target data input/output pin. The second input terminal receives, when the memory is in the working mode, the working serial data received by each data input/output pin, and transmits the working serial data to a first selector corresponding to the target data input/output pin. The serial-to-parallel circuit 102 is configured to convert the received test serial data into test parallel data when the memory is in the test mode. The serial-to-parallel circuit 102 is configured to convert the received multiple pieces of working serial data into corresponding working parallel data when the memory is in the working mode, and transmit each of the multiple pieces of working parallel data to a first selector corresponding to a corresponding data input/output pin.

Correspondingly, the first input terminal of the data input/output selector 101 may receive the test parallel data when the memory is in the test mode, and the second input terminal of the data input/output selector 101 may receive the working parallel data corresponding to each data input/output pin when the memory is in the working mode.

In this example, as shown in FIG. 5, the serial-to-parallel circuit 102 may include multiple serial-to-parallel sub-circuits 1021. An input terminal of each of the serial-to-parallel sub-circuits 1021 is connected to one data input/output pin. A serial-to-parallel sub-circuit corresponding to the target data input/output pin is configured to convert the test serial data into test parallel data when the memory is in the test mode, and a serial-to-parallel sub-circuit corresponding to each data input/output pin is configured to convert corresponding working serial data into working parallel data when the memory is in the working mode.

In an actual application, when the memory is in the working mode, after converting, into working parallel data, working serial data received by a connected data input/output pin, each of the serial-to-parallel sub-circuits 1021 may transmit the working parallel data to one corresponding first selector. The serial-to-parallel sub-circuit corresponding to the target data input/output pin may further transmit each bit of data in the test parallel data to each first selector when the memory is in the test mode. For example, the first input terminal of each of the first selectors 1011 may successively receive 1-bit data in test parallel data corresponding to the target data input/output pin based on a sequence of transmitting each bit of data in multi-bit test serial data received by the target data input/output pin. Therefore, each of the first selectors 1011 can receive 1-bit data in the test parallel data corresponding to the target data input/output pin. This reduces a possibility of a transmission error. Similarly, the second input terminal of each of the second selectors may successively receive 1-bit data in working parallel data corresponding to a corresponding data input/output pin based on a sequence of transmitting each bit of data in multi-bit working serial data received by the corresponding data input/output pin. Therefore, each of the second selectors can receive 1-bit data in the working parallel data corresponding to the corresponding data input/output pin. This also reduces a possibility of a data transmission error.

That the target data input/output pin is the DQ7 pin is taken as an example. When the memory is in the test mode, the serial-to-parallel circuit separately converts, into 16 pieces of 1-bit test parallel data, 16-bit test serial data received by the DQ7 pin. The 16 pieces of 1-bit test parallel data are respectively denoted as burst0 to burst15. Each piece of 1-bit data corresponds to one first selector, and 16 selectors are respectively denoted as mux0 to mux15.

With reference to FIG. 6 and FIG. 11, when the memory is in the test mode, a first input terminal of mux0 receives burst0, and transmits burst0 to transmission paths corresponding to the DQ0 pin; a first input terminal of mux1 receives burst1, and transmits burst1 to transmission paths corresponding to the DQ1 pin; a first input terminal of mux2 receives burst2, and transmits burst2 to transmission paths corresponding to the DQ2 pin; a first input terminal of mux3 receives burst3, and transmits burst3 to transmission paths corresponding to the DQ3 pin; a first input terminal of mux4 receives burst4, and transmits burst4 to transmission paths corresponding to the DQ4 pin; a first input terminal of mux5 receives burst5, and transmits burst5 to transmission paths corresponding to the DQ5 pin; a first input terminal of mux6 receives burst6, and transmits burst6 to transmission paths corresponding to the DQ6 pin; a first input terminal of mux7 receives burst7, and transmits burst7 to transmission paths corresponding to the DQ7 pin; a first input terminal of mux8 receives burst8, and transmits burst8 to transmission paths corresponding to the DQ8 pin; a first input terminal of mux9 receives burst9, and transmits burst9 to transmission paths corresponding to the DQ9 pin; a first input terminal of mux10 receives burst10, and transmits burst10 to transmission paths corresponding to the DQ10 pin; a first input terminal of mux11 receives burst11, and transmits burst11 to transmission paths corresponding to the DQ11 pin; a first input terminal of mux12 receives burst12, and transmits burst12 to transmission paths corresponding to the DQ12 pin; a first input terminal of mux13 receives burst13, and transmits burst13 to transmission paths corresponding to the DQ13 pin; a first input terminal of mux14 receives burst14, and transmits burst14 to transmission paths corresponding to the DQ14 pin; and a first input terminal of mux15 receives burst15, and transmits burst15 to transmission paths corresponding to the DQ15 pin.

In some embodiments, the memory may further include a latch circuit 103. As shown in FIG. 5, an input terminal of the latch circuit 103 is connected to an output terminal of the serial-to-parallel circuit 102, and an output terminal of the latch circuit 103 is connected to the multiple first selectors 1011 in the data input/output selector 101. The input terminal of the latch circuit 103 may include a first input terminal and a second input terminal. The first input terminal of the latch circuit 103 receives the test parallel data of the output terminal of the serial-to-parallel circuit when the memory is in the test mode. The second input terminal of the latch circuit 103 receives, when the memory is in the working mode, the multiple pieces of working parallel data output by the serial-to-parallel circuit. When the memory is in the test mode, the latch circuit 103 is configured to store the test parallel data, and separately transmit each bit of data in the test parallel data to one corresponding first selector after a write command is received. When the memory is in the working mode, the latch circuit 103 is configured to store the multiple pieces of working parallel data, and separately transmit each piece of working parallel data to one corresponding first selector after the write command is received. Therefore, each of the first selectors 1011 can receive working parallel data corresponding to one data input/output pin when the memory is in the working mode, and can receive 1-bit data in the test parallel data when the memory is in the test mode.

In this example, as shown in FIG. 6, the latch circuit 103 may include multiple latch sub-circuits 1031, an input terminal of each of the latch sub-circuits 1031 is connected to one serial-to-parallel sub-circuit 1021, and an output terminal of each of the latch sub-circuits 1031 is connected to one first selector 1011. When the memory is in the test mode, a latch sub-circuit 1031 corresponding to the target data input/output pin receives the test parallel data, stores the test parallel data, and separately transmits each bit of data in the test parallel data to one corresponding first selector after the write command is received. When the memory is in the working mode, each of the latch sub-circuits 1031 receives corresponding working parallel data, stores the corresponding working parallel data, and transmits, to one corresponding first selector after the write command is received, the working parallel data stored by the latch sub-circuit.

As shown in FIG. 7, each of the latch sub-circuits 1031 may include multiple latches 1032, each of the latches 1032 is connected to one of the second selectors 1012, and each of the second selectors 1012 corresponds to one transmission path. When the memory is in the test mode, each latch in the latch sub-circuit corresponding to the target data input/output pin receives 1-bit data in the test parallel data, stores the 1-bit data in the test parallel data, and transmits, to a corresponding second selector after the write command is received, the 1-bit data in the test parallel data stored by the latch. When the memory is in the working mode, each latch in the latch sub-circuit corresponding to each data input/output pin separately stores 1-bit data in working parallel data output by a corresponding serial-to-parallel sub-circuit, and transmits, to a corresponding second selector after the write command is received, the 1-bit data in the working parallel data stored by the latch.

In some embodiments, as shown in FIG. 11, the memory further includes a data mask pin DMI0/DMI1. The data mask pin is configured to: receive mask data (for example, perform a mask write operation) when the memory is in the working mode, or receive check code data when the memory is in the test mode. When the memory is in the working mode, the memory masks, based on mask data, data received by the data input/output pin. When the memory is in the test mode, the memory stores the check code data into a check code memory array. The memory masks, based on the check code data, the data received by the data input/output pin.

In this example, the memory further includes a check code data selector, the check code memory array includes a first check code memory array and a second check code memory array, and the data mask pin includes a first data mask pin and a second data mask pin. When the memory is in the test mode, if the first data mask pin receives the check code data, the check code data selector transmits the check code data to transmission paths corresponding to the first data mask pin and the second data mask pin, the first check code memory array receives and stores the check code data through the transmission paths corresponding to the first data mask pin, and the second check code memory array receives and stores the check code data through the transmission paths corresponding to the second data mask pin.

A quantity of bits of the check code data is the same as a quantity of bits of the serial data received by each data input/output pin. When the memory is in the test mode, the memory masks data corresponding to each data input/output pin based on each bit of data in the check code data. For example, both the check code data and the serial data received by the data input/output pin are 16-bit data, and each bit of data in the check code data is configured to mask 1-bit data corresponding to each data input/output pin.

In an actual application, the memory includes a DMI0 pin and a DMI1 pin. Generally, mask data received by the DMI0 pin is configured to control whether parallel data corresponding to the DQ0 to DQ7 pins is to be written into the primary memory array, and mask data received by the DMI1 pin is configured to control whether parallel data corresponding to the DQ8 to DQ15 pins is to be written into the primary memory array. In this embodiment, when the memory is in the test mode, if the DMI0 pin receives the check code data, the check code data selector may transmit, to transmission paths corresponding to the DMI0 pin and transmission paths corresponding to the DMI1 pin, the check code data received by the DMI0 pin. If the DMI1 pin receives the check code data, the check code data selector may transmit, to transmission paths corresponding to the DMI0 pin and transmission paths corresponding to the DMI1 pin, the check code data received by the DMI1 pin. This reduces a quantity of utilized DMI pins in a test process, and improves test efficiency.

For example, the check code data selector may include multiple third selectors. In the test mode, each of the third selectors can transmit 1-bit data in the check code data to one transmission path corresponding to the first data mask pin and one transmission path corresponding to the second data mask pin, and the multiple third selectors can transmit each bit of data in the check code data to multiple transmission paths corresponding to the first data mask pin and multiple transmission paths corresponding to the second data mask pin.

In an actual application, serial check code data received by the data mask pin may be converted into parallel check code data. For example, the serial check code data is one piece of 16-bit serial data, and the 16-bit serial data is converted into 16-bit parallel data. Then, one of the third selectors transmits 1-bit data thereof to one transmission path corresponding to the first data mask pin and one transmission path corresponding to the second data mask pin.

The memory provided in the embodiments of the present disclosure is described in detail above. According to the memory provided in the embodiments of the present disclosure, during a memory test, only one data input/output pin is required, so that a quantity of utilized data input/output pins is reduced, thereby increasing a quantity of simultaneously tested memories, and improving test efficiency. In addition, in the test process, the data in the test serial data and the reverse data of the data in the test serial data can be transmitted to the transmission paths corresponding to the data input/output pins, to expand a data pattern, and increase a test coverage.

A person skilled in the art can easily figure out other implementation solutions of the present disclosure after considering the specification and practice of the present disclosure herein. The present disclosure is intended to cover any variations, functions, or adaptive changes of the present disclosure. These variations, functions, or adaptive changes comply with general principles of the present disclosure, and include common knowledge or a conventional technical means in the art that is not disclosed in the present disclosure. The specification and embodiments are merely considered as examples, and the true scope and spirit of the present disclosure are pointed out in the following claims.

It should be understood that the present disclosure is not limited to the precise structures described above and shown in the accompanying drawings, and various modifications and changes may be made without departing from the scope thereof. The scope of the present disclosure is limited only by the appended claims.

### INDUSTRIAL APPLICABILITY

The memory provided in the embodiments of the present disclosure includes multiple data input/output pins and a data input/output selector. One of the multiple data input/output pins is a target data input/output pin. The multiple data input/output pins are configured to receive or output working serial data when the memory is in a working mode. The target data input/output pin is configured to receive test serial data when the memory is in a test mode. A first input terminal of the data input/output selector receives the test serial data received by the target data input/output pin. A first control terminal thereof receives a test enable signal group. A second control terminal thereof receives a reverse enable signal group. A third control terminal thereof receives a working enable signal. When the memory is in the test mode, the data input/output selector is configured to separately transmit data in the test serial data to a part of transmission paths corresponding to one corresponding data input/output pin based on the test enable signal group, and the data input/output selector is further configured to separately transmit, to another part of transmission paths corresponding to the one corresponding data input/output pin based on the reverse enable signal group, reverse data generated after reversing data in the test serial data. When the memory is in the working mode, the data input/output selector transmits, to respective corresponding transmission paths based on the working enable signal, working serial data received by various data input/output pins. Therefore, during a memory test, only one data input/output pin is required, so that a quantity of data input/output pins is reduced, thereby increasing a quantity of simultaneously tested memories, and improving test efficiency. In addition, in the test process, the data in the test serial data and the reverse data of the data in the test serial data can be transmitted to the transmission paths corresponding to the data input/output pins, to expand a data pattern, and increase a test coverage.

What is claimed is:

1. A memory, comprising:
a plurality of data input/output pins, configured to receive or output working serial data when the memory is in a working mode, one of the data input/output pins being a target data input/output pin, and the target data input/output pin being configured to receive test serial data when the memory is in a test mode; and
a data input/output selector, a first input terminal of the data input/output selector receiving the test serial data received by the target data input/output pin, and
the data input/output selector being configured to: in the test mode, separately transmit, to transmission paths corresponding to one corresponding data input/output pin in the memory, each bit of data in the test serial data received by the target data input/output pin.

2. The memory according to claim 1, wherein a second input terminal of the data input/output selector receives a plurality of pieces of working serial data received by the plurality of data input/output pins; and
the data input/output selector is further configured to: in the working mode, separately transmit, to the transmission paths corresponding to the one corresponding data input/output pin, working serial data received by the one corresponding data input/output pin.

3. The memory according to claim 2, wherein the data input/output selector comprises a plurality of first selectors, and each of the first selectors corresponds to one data input/output pin;
a first input terminal of each of the first selectors receives 1-bit data in the test serial data received by the target data input/output pin, and a second input terminal of each of the first selectors receives working serial data received by a corresponding data input/output pin; and
each of the first selectors is configured to: in the test mode, transmit, to various transmission paths of the corresponding data input/output pin, 1-bit data in the test serial data received by the target data input/output pin; and in the working mode, transmit, to transmission paths of the corresponding data input/output pin, the working serial data received by the corresponding data input/output pin.

4. The memory according to claim 3, wherein each of the first selectors comprises a plurality of second selectors, and each of the second selectors corresponds to one transmission path of one data input/output pin;
a first input terminal of each of the second selectors receives 1-bit data in the test serial data received by the target data input/output pin, and a second input terminal of each of the second selectors receives 1-bit data in working serial data received by a corresponding data input/output pin; and
each of the second selectors is configured to: in the test mode, transmit, to one transmission path of the corresponding data input/output pin, 1-bit data in the test serial data received by the target data input/output pin; and in the working mode, transmit, to one transmission path of the corresponding data input/output pin, 1-bit data in working serial data received by the corresponding data input/output pin.

5. The memory according to claim 1, wherein
for the data input/output selector, a first control terminal of the data input/output selector receives a test enable signal group, a second control terminal of the data input/output selector receives a reverse enable signal group, and a third control terminal of the data input/output selector receives a working enable signal;
when the memory is in the test mode, the data input/output selector is configured to separately transmit data in the test serial data to a part of transmission paths corresponding to the one corresponding data input/output pin based on the test enable signal group, and the data input/output selector is further configured to separately transmit, to another part of transmission paths corresponding to the one corresponding data input/output pin based on the reverse enable signal group, reverse data generated after reversing the data in the test serial data; and
when the memory is in the working mode, the data input/output selector separately transmits, to respective corresponding transmission paths based on the working enable signal, working serial data received by various data input/output pins.

6. The memory according to claim 5, wherein all transmission paths corresponding to any one of the data input/output pins receive a same bit of data in the test serial data.

7. The memory according to claim 6, wherein the data input/output selector comprises a plurality of first selectors, each of the first selectors corresponds to one data input/output pin, the test enable signal group comprises a plurality of test enable signals, and the reverse enable signal group comprises a plurality of reverse enable signals;
a first input terminal of each of the first selectors receives 1-bit data in the test serial data when the memory is in the test mode, a second input terminal of each of the first selectors receives, when the memory is in the working mode, working serial data received by a corresponding data input/output pin, a first control terminal of each of the first selectors receives one of the test enable signals, a second control terminal of each of the first selectors receives one of the reverse enable signals, and a third control terminal of each of the first selectors receives the working enable signal;
when the memory is in the test mode, the first selector is configured to transmit, to a part of transmission paths corresponding to the data input/output pin corresponding to the first selector based on the test enable signal received by the first control terminal of the first selector, data received by the first input terminal of the first selector, and the first selector is further configured to transmit, to another part of transmission paths based on the reverse enable signal received by the second control terminal of the first selector, reverse data generated after reversing the data received by the first input terminal of the first selector; and
when the memory is in the working mode, the first selector is configured to transmit, to corresponding transmission paths based on the working enable signal, the working serial data received by the corresponding data input/output pin.

8. The memory according to claim 7, wherein each of the first selectors comprises a plurality of second selectors, each of the second selectors corresponds to one transmission path of one data input/output pin, the test enable signal comprises a plurality of test enable sub-signals, and the reverse enable signal comprises a plurality of reverse enable sub-signals;
a first input terminal of each of second selectors in a same first selector receives 1-bit data in the test serial data when the memory is in the test mode, a second input terminal receives, when the memory is in the working mode, 1-bit data in working serial data received by a corresponding data input/output pin, a first control terminal receives one of the test enable sub-signals, a second control terminal receives one of the reverse enable sub-signals, and a third control terminal receives the working enable signal;
when the memory is in the test mode, the second selector is configured to: transmit, to one transmission path corresponding to the second selector based on the test enable sub-signal received by the first control terminal of the second selector, data received by the first input terminal of the second selector, or the second selector transmits, to one transmission path corresponding to the second selector based on the reverse enable sub-signal received by the second control terminal of the second selector, reverse data generated after reversing data received by the first input terminal of the second selector; and
when the memory is in the working mode, the second selector is configured to transmit, to a corresponding transmission path based on the working enable signal, data received by the second input terminal of the second selector.

9. The memory according to claim 8, wherein the second selector comprises:
a first control circuit, an input terminal of the first control circuit receiving 1-bit data in the test serial data when the memory is in the test mode, a first control terminal of the first control circuit receiving the test enable sub-signal, a second control terminal of the first control circuit receiving the reverse enable sub-signal, and the first control circuit being configured to: transmit, to the transmission path corresponding to the second selector based on the test enable sub-signal received by the first control terminal of the first control circuit, data received by the input terminal of the first control circuit, or transmit, to the transmission path corresponding to the second selector based on the reverse enable sub-signal received by the second control terminal of the first control circuit, reverse data generated after reversing data received by the input terminal of the first control circuit; and
a second control circuit, an input terminal of the second control circuit receiving, when the memory is in the working mode, 1-bit data in working serial data received by a corresponding data input/output pin, a control terminal of the second control circuit receiving the working enable signal, and the second control circuit being configured to transmit, to the transmission path corresponding to the second selector based on the working enable signal, data received by the input terminal of the second control circuit.

10. The memory according to claim 9, wherein the first control circuit comprises:
a first transmission gate, an input terminal of the first transmission gate serving as the input terminal of the first control circuit, a first control terminal of the first transmission gate serving as the first control terminal of the first control circuit, a second control terminal of the first transmission gate receiving an inverted signal of the test enable sub-signal, and an output terminal of the first transmission gate serving as an output terminal of the first control circuit; and
a gated inverter, an input terminal of the gated inverter serving as the input terminal of the first control circuit, a first control terminal of the gated inverter serving as the second control terminal of the first control circuit, a second control terminal of the gated inverter receiving an inverted signal of the reverse enable sub-signal, and an output terminal of the gated inverter serving as the output terminal of the first control circuit; and
the second control circuit comprises:
a second transmission gate, an input terminal of the second transmission gate serving as the input terminal of the second control circuit, a first control terminal of the second transmission gate serving as the control terminal of the second control circuit, a second control terminal of the second transmission gate receiving an inverted signal of the working enable signal, and an output terminal of the second transmission gate serving as an output terminal of the second control circuit.

11. The memory according to claim 10, further comprising:
a first signal generation circuit, an input terminal of the first signal generation circuit receiving a test indication signal, the first signal generation circuit being configured to generate the working enable signal based on the test indication signal, and the working enable signal and the test indication signal being mutually inverted signals;
a plurality of second signal generation circuits, a first input terminal of each of the second signal generation circuits receiving the test indication signal, a second input terminal of each of the second signal generation circuits receiving a reverse indication sub-signal, an output terminal of each of the second signal generation circuits being connected to at least a first control terminal and a second control terminal of one of the second selectors, and each of the second signal generation circuits being configured to generate the reverse enable sub-signal and the test enable sub-signal based on the test indication signal and the reverse indication sub-signal.

12. The memory according to claim 11, wherein the second signal generation circuit comprises:
a first sub-circuit, the first sub-circuit being configured to generate the test enable sub-signal based on an inverted signal of the reverse indication sub-signal and the test indication signal; and
a second sub-circuit, the second sub-circuit being configured to generate the reverse enable sub-signal based on the reverse indication sub-signal and the test indication signal, and a reverse enable sub-signal and a test enable sub-signal generated by a same second signal generation circuit are mutually inverted signals; wherein the first sub-circuit comprises: a first NAND gate, a first input terminal of the first NAND gate receiving the test indication signal, a second input terminal of the first NAND gate receiving the inverted signal of the reverse indication sub-signal, and an output terminal of the first NAND gate outputting the inverted signal of the test enable sub-signal; and
a sixth NOT gate, an input terminal of the sixth NOT gate being connected to the output terminal of the first NAND gate, and an output terminal of the sixth NOT gate outputting the test enable sub-signal; and
the second sub-circuit comprises:
a second NAND gate, a first input terminal of the second NAND gate receiving the test indication signal, a second input terminal of the second NAND gate receiving the reverse indication sub-signal, and an output terminal of the second NAND gate outputting the inverted signal of the reverse enable sub-signal; and
a seventh NOT gate, an input terminal of the seventh NOT gate being connected to the output terminal of the second NAND gate, and an output terminal of the seventh NOT gate outputting the reverse enable sub-signal; wherein the first signal generation circuit comprises:
an eighth NOT gate, an input terminal of the eighth NOT gate receiving the test indication signal, and an output terminal of the eighth NOT gate outputting the working enable signal; and
a ninth NOT gate, an input terminal of the ninth NOT gate being connected to the output terminal of the eighth NOT gate, and an output terminal of the ninth NOT gate outputting the inverted signal of the working enable signal.

13. The memory according to claim 1, comprising:
a serial-to-parallel circuit, a first input terminal of the serial-to-parallel circuit receiving the test serial data when the memory is in the test mode, and a second input terminal of the serial-to-parallel circuit receiving, when the memory is in the working mode, the working serial data received by each data input/output pin;
the serial-to-parallel circuit being configured to convert the test serial data into test parallel data when the memory is in the test mode; and
the serial-to-parallel circuit being configured to convert each piece of working serial data into corresponding working parallel data when the memory is in the working mode.

14. The memory according to claim 13, wherein the serial-to-parallel circuit comprises a plurality of serial-to-parallel sub-circuits, and an input terminal of each of the serial-to-parallel sub-circuits is connected to one data input/output pin;
a serial-to-parallel sub-circuit corresponding to the target data input/output pin is configured to convert the test serial data into test parallel data when the memory is in the test mode; and
a serial-to-parallel sub-circuit corresponding to each data input/output pin is configured to convert corresponding working serial data into working parallel data when the memory is in the working mode.

15. The memory according to claim 14, comprising:
a latch circuit, a first input terminal of the latch circuit receiving, when the memory is in the test mode, test parallel data output by the serial-to-parallel circuit, and a second input terminal of the latch circuit receiving, when the memory is in the working mode, a plurality of pieces of working parallel data output by the serial-to-parallel circuit;
when the memory is in the test mode, the latch circuit being configured to: store the test parallel data, and separately transmit each bit of data in the test parallel data to one corresponding first selector after a write command is received; and
when the memory is in the working mode, the latch circuit being configured to: store the plurality of pieces of working parallel data, and separately transmit the plurality of pieces of working parallel data to one corresponding first selector after the write command is received.

16. The memory according to claim 15, wherein the latch circuit comprises a plurality of latch sub-circuits, an input terminal of each of the latch sub-circuits is connected to an output terminal of one serial-to-parallel sub-circuit, and an output terminal of each of the latch sub-circuits is connected to one first selector;
when the memory is in the test mode, a latch sub-circuit corresponding to the target data input/output pin is configured to: store the test parallel data, and separately transmit each bit of data in the test parallel data to one corresponding first selector after the write command is received; and
when the memory is in the working mode, a latch sub-circuit corresponding to each data input/output pin is configured to: store working parallel data output by a corresponding serial-to-parallel sub-circuit, and transmit, to the one corresponding first selector after the write command is received, the working parallel data stored by the latch sub-circuit;
wherein each of the latch sub-circuits comprises a plurality of latches, and each of the latches is connected to one of the second selectors;
when the memory is in the test mode, each latch in the latch sub-circuit corresponding to the target data input/output pin is separately configured to: store 1-bit data in the test parallel data, and transmit, to a corresponding second selector after the write command is received, the 1-bit data in the test parallel data stored by the latch; and
when the memory is in the working mode, each latch in the latch sub-circuit corresponding to each data input/output pin is separately configured to: store 1-bit data in working parallel data output by a corresponding serial-to-parallel sub-circuit, and transmit, to a corresponding second selector after the write command is received, the 1-bit data in the working parallel data stored by the latch.

17. The memory according to claim 1, further comprising:
a data mask pin, configured to: receive mask data when the memory is in the working mode, or receive check code data when the memory is in the test mode, the memory masking, based on the mask data when the memory is in the working mode, data received by the data input/output pin, and storing the check code data into a check code memory array when the memory is in the test mode;
a check code data selector, the check code memory array comprising a first check code memory array and a second check code memory array, the data mask pin comprising a first data mask pin and a second data mask pin, if the first data check code pin receiving the check code data when the memory is in the test mode, the check code data selector separately transmitting the check code data to transmission paths corresponding to the first data mask pin and the second data mask pin, the first check code memory array receiving and storing the check code data through the transmission paths corresponding to the first data mask pin, and the second check code memory array receiving and storing the check code data through the transmission paths corresponding to the second data mask pin.

18. The memory according to claim 17, wherein the check code data selector comprises a plurality of third selectors, and in the test mode, each of the third selectors transmits 1-bit data in the check code data to one transmission path corresponding to the first data mask pin and one transmission path corresponding to the second data mask pin.

19. The memory according to claim 18, wherein the memory comprises a primary memory array, and the primary memory array stores data on transmission paths corresponding to the data input/output pin; wherein in the test mode, the primary memory array receives and stores, through the transmission paths corresponding to each of the data input/output pins, the test serial data received by the target data input/output pin.
